(19) United States
(12) Patent Application Publication
(10) Pub. No.: US 2022/0352444 A1
(43) Pub. Date: Nov. 3, 2022

(54) DISPLAY DEVICE

(71) Applicant: Samsung Display Co., LTD., Yongin-si (KR)

(72) Inventors: Joo Woan CHO, Seongnam-si (KR); Sung Kook PARK, Suwon-si (KR); Dae Ho SONG, Hwaseong-si (KR); Byung Choon YANG, Seoul (KR); Hyung Il JEON, Seoul (KR); Jin Woo CHOI, Seoul (KR)

(21) Appl. No.: 17/571,322

(22) Filed: Jan. 7, 2022

(30) Foreign Application Priority Data
Apr. 30, 2021 (KR) 10-2021-0056691

(51) Int. Cl. H01L 33/62; H01L 33/38; H01L 33/64; H01L 27/15

(52) U.S. Cl. CPC H01L 33/62; H01L 33/382; H01L 33/642; H01L 27/156

(57) ABSTRACT

A display device includes a first substrate, light emitting elements and a connection electrode on a first surface of the first substrate, and electrically connected to the light emitting elements, first pads spaced from the connection electrode in a direction, second pads spaced from the connection electrode in another direction, a circuit board including a first circuit board pad and a second circuit board pad, a first pad connection electrode connected to the first pads and the first circuit board pad, and including a first connection part in a first via hole passing through the first substrate, and a first electrode part on the first substrate, and a second pad connection electrode connected to the second pads and the second circuit board pad, and including a second connection part in a second via hole passing through the first substrate, and a second electrode part on the first substrate.

### CROSS-REFERENCE TO RELATED APPLICATION

This application claims priority to, and the benefit of, Korean Patent Application No. 10-2021-0056691 filed on Apr. 30, 2021 in the Korean Intellectual Property Office, the contents of which in its entirety are herein incorporated by reference.

### BACKGROUND

### 1. Field

The disclosure relates to a display device.

### 2. Description of the Related Art

As the information society develops, demands for display devices for displaying images are increasing in various forms. The display devices may be flat panel displays, such as liquid crystal displays, field emission displays, and light emitting displays. The light emitting displays may include an organic light emitting display including an organic light emitting diode element as a light emitting element, or an inorganic light emitting display including an inorganic semiconductor element as a light emitting element.

Recently, a head-mounted display including a light emitting display has been developed. The head-mounted display is a virtual reality (VR) or augmented reality (AR) glasses-type monitor device that is worn by a user in the form of glasses or a helmet, and forms a focus at a relatively short distance in front of the eyes.

### SUMMARY

Aspects of the disclosure provide an ultra-high resolution display device that includes inorganic light emitting elements, and that includes a large number of light emitting elements per unit area.

Aspects of the disclosure also provide a display device in which an area occupied by an emission area per unit area is large.

However, aspects of the disclosure are not restricted to the one set forth herein. The above and other aspects of the disclosure will become more apparent to one of ordinary skill in the art to which the disclosure pertains by referencing the detailed description of the disclosure given below.

According to some embodiments of the disclosure, a display device includes a first substrate including a display area, and a non-display area on at least one side of the display area, light emitting elements on a first surface of the first substrate in the display area, a connection electrode on the first surface of the first substrate in the non-display area, and electrically connected to the light emitting elements, first pads in the non-display area and spaced from the connection electrode in a direction, second pads spaced from the connection electrode in another direction, a circuit board on a second surface of the first substrate, and including a first circuit board pad and a second circuit board pad on a first surface of the circuit board, a first pad connection electrode connected to the first pads and the first circuit board pad, and including a first connection part in a first via hole corresponding to the first pads and passing through the first substrate, and a first electrode part on the second surface of the first substrate, and a second pad connection electrode connected to the second pads and the second circuit board pad, and including a second connection part in a second via hole corresponding to the second pads and passing through the first substrate, and a second electrode part on the second surface of the first substrate.

A distance between a light emitting element in an outermost part of the display area among the light emitting elements and the first pads may be greater than a distance between the light emitting element in the outermost part of the display area and the second pads.

The first connection part may directly contact the first pads, wherein the second connection part directly contacts the second pads, wherein the first electrode part directly contacts the first circuit board pad, and wherein the second electrode part directly contacts the second circuit board pad.

The first electrode part of the first pad connection electrode and the first circuit board pad may correspond to the first pads, wherein the second electrode part of the second pad connection electrode and the second circuit board pad correspond to the second pads.

The first substrate may include a first substrate layer in which the first via hole and the second via hole are formed, and a second substrate layer on a lower surface of the first substrate layer and in which third via holes and fourth via holes are formed, wherein the first pad connection electrode further includes a third connection part in the third via holes, and a third electrode part that contacts first connection parts and the third connection part, and wherein the second pad connection electrode further includes a fourth connection part in the fourth via holes, and a fourth electrode part that contacts second connection parts and the fourth connection part.

A number of first electrode parts of the first pad connection electrode and a number of first circuit board pads may be fewer than a number of first pads.

The display device may further include a heat dissipation layer between the first substrate and the circuit board in the display area, wherein the circuit board is below the second surface of the first substrate to overlap the non-display area and a part of the display area.

The heat dissipation layer may overlap the light emitting elements, and may directly contact the second surface of the first substrate and the first surface of the circuit board.

The display device may further include a heat dissipation pattern directly contacting the heat dissipation layer and located in fifth via holes corresponding to at least some of the light emitting elements and passing through the first substrate.

The fifth via holes may correspond to the light emitting elements in the display area.

The first pad connection electrode and the second pad connection electrode may include a same material as the heat dissipation pattern.

The first substrate may include pixel electrodes that correspond to the light emitting elements in the display area, and a common electrode that corresponds to the connection electrode in the non-display area, wherein the fifth via holes pass through at least some of the pixel electrodes.

The display device may further include a heat dissipation substrate on a second surface of the circuit board and located in the display area and the non-display area.

The circuit board may define an open hole corresponding to the display area, wherein the display device further includes a heat dissipation layer in the open hole of the circuit board to contact the second surface of the first substrate.

The display device may further include a heat dissipation substrate on the second surface of the circuit board and located in the display area and the non-display area, wherein a part of the heat dissipation substrate in the display area directly contacts the heat dissipation layer.

The light emitting elements each may include a first semiconductor layer, an active layer on the first semiconductor layer, and a second semiconductor layer on the active layer, wherein the display device further includes a third semiconductor layer above the first substrate and located on a surface of the second semiconductor layer of the light emitting elements, and wherein the connection electrode is directly on the first semiconductor layer.

The second semiconductor layers of the light emitting elements may be connected to each other through a base layer thereof that is located on a surface of the third semiconductor layer in the display area and the non-display area.

According to some embodiments of the disclosure, display device includes a first substrate including a display area in which light emitting elements are located, and a non-display area surrounding the display area, common electrodes in the non-display area to surround the display area and spaced apart from each other, first pads outside the common electrodes in the non-display area, second pads between the common electrodes and the display area, a circuit board on a second surface of the first substrate, which is opposite to a first surface of the first substrate on which the light emitting elements are located, and including first circuit board pads and second circuit board pads, first pad connection electrodes in first via holes passing through the first substrate and corresponding to the first pads, and respectively contacting the first pads and the first circuit board pads, and second pad connection electrodes in second via holes passing through the first substrate and corresponding to the second pads, and respectively contacting the second pads and the second circuit board pads.

The light emitting elements may be arranged in a first direction, and in a second direction intersecting the first direction, wherein the first pads are spaced apart from at least some of the common electrodes in the first direction, and wherein the second pads are spaced apart from at least some of the common electrodes in a direction that is opposite to the first direction.

At least some of the first pads might not be located side by side with the second pads in the first direction.

The display device may further include a heat dissipation layer overlapping the light emitting elements in the display area, and directly contacting the second surface of the first substrate.

The display device may further include heat dissipation patterns directly contacting the heat dissipation layer, and located in third via holes passing through the first substrate and corresponding to at least some of the light emitting elements.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a display device according to some embodiments;

FIG. 2 is a plan view of a part A of FIG. 1;

FIG. 3 is a plan view of a part B of FIG. 2;

FIG. 4 is a cross-sectional view taken along the line L1-L1′ of FIG. 2;

FIG. 5 is a cross-sectional view of a light emitting element according to some embodiments;

FIG. 6 is a plan view illustrating the arrangement of light emitting elements of the display device according to the embodiment;

FIG. 7 is a plan view illustrating the arrangement of color filters of the display device according to the embodiment;

FIG. 8 is a plan view illustrating the arrangement of pad electrodes and common electrodes in pad areas and a common electrode connection part of the display device according to the embodiment;

FIG. 9 is a cross-sectional view taken along the lines L2-L2′ and L3-L3′ of FIG. 8;

FIG. 10 is a cross-sectional view of a part of a display device according to some embodiments;

FIG. 11 is a cross-sectional view of a part of a display device according to some embodiments;

FIG. 12 is a plan view illustrating the relative arrangement of a circuit board and a display panel of the display device of FIG. 11;

FIG. 13 is a cross-sectional view of a part of a display device according to some embodiments;

FIG. 14 is a plan view illustrating the arrangement of third via holes formed in emission areas of the display device of FIG. 13;

FIG. 15 is a cross-sectional view of a part of a display device according to some embodiments;

FIG. 16 is a plan view illustrating the arrangement of third via holes formed in emission areas of the display device of FIG. 15;

FIG. 17 is a cross-sectional view of pad electrodes located in pad areas of a display device according to some embodiments;

FIG. 18 is a cross-sectional view of a part of the display device of FIG. 17;

FIG. 19 is a circuit diagram of a pixel circuit unit and a light emitting element according to some embodiments;

FIG. 20 is a circuit diagram of a pixel circuit unit and a light emitting element according to some embodiments;

FIG. 21 is a circuit diagram of a pixel circuit unit and a light emitting element according to some embodiments;

FIGS. 22 through 24 are schematic views of devices including a display device according to some embodiments; and

FIGS. 25 and 26 illustrate a transparent display device including a display device according to some embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present.

In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section.

Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein.

Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

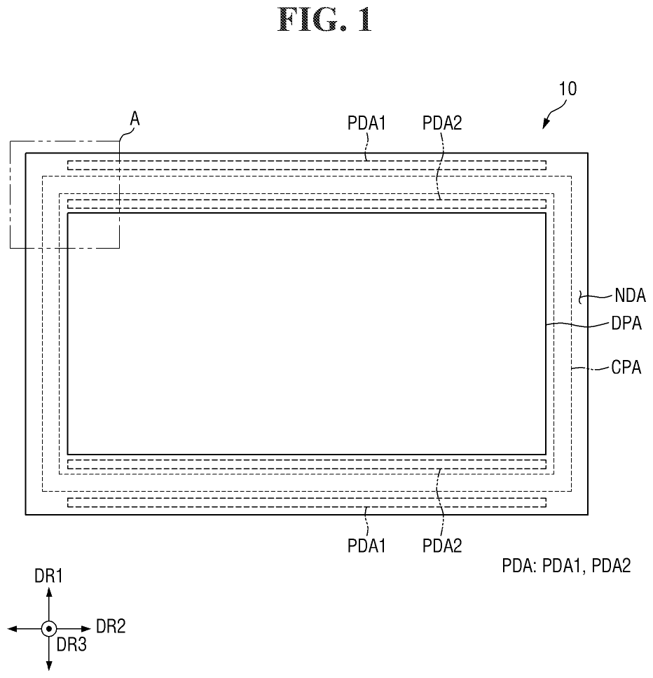

FIG. 1 is a schematic plan view of a display device 10 according to some embodiments.

Referring to FIG. 1, the display device 10 displays moving images or still images. The display device 10 may refer to any electronic device that provides a display screen. Examples of the display device 10 may include televisions, notebook computers, monitors, billboards, the Internet of things (IoT), mobile phones, smartphones, tablet personal computers (PCs), electronic watches, smart watches, watch phones, head-mounted displays, mobile communication terminals, electronic notebooks, electronic books, portable multimedia players (PMPs), navigation devices, game machines, digital cameras, and camcorders, all of which provide a display screen.

The display device 10 includes a display panel that provides a display screen. Examples of the display panel may include inorganic light emitting diode display panels, organic light emitting display panels, quantum dot light emitting display panels, plasma display panels, and field emission display panels. A display panel in which inorganic light emitting diodes are located on a semiconductor circuit board will be described below as an example of the display panel, but the disclosure is not limited to this case, and other display panels can also be applied.

The shape of the display device 10 can be variously modified. For example, the display device 10 may have various shapes, such as a horizontally long rectangle, a vertically long rectangle, a square, a quadrangle with rounded corners (vertices), other polygons, and a circle. The shape of a display area DPA of the display device 10 may also be similar to the overall shape of the display device 10. In FIG. 1, the display device 10 shaped like a rectangle that is long in a second direction DR2 is illustrated.

The display device 10 may include the display area DPA and a non-display area NDA. The display area DPA may be an area where a screen can be displayed, and the non-display area NDA may be an area where no screen is displayed. The display area DPA may also be referred to as an active area, and the non-display area NDA may also be referred to as an inactive area. The display area DPA may generally occupy the center of the display device 10.

The non-display area NDA may be located around the display area DPA. The non-display area NDA may entirely or partially surround the display area DPA. The display area DPA may be rectangular, and the non-display area NDA may be adjacent to four sides of the display area DPA. The non-display area NDA may form a bezel of the display device 10. In each non-display area NDA, wirings or circuit drivers included in the display device 10 may be located, or external devices may be mounted.

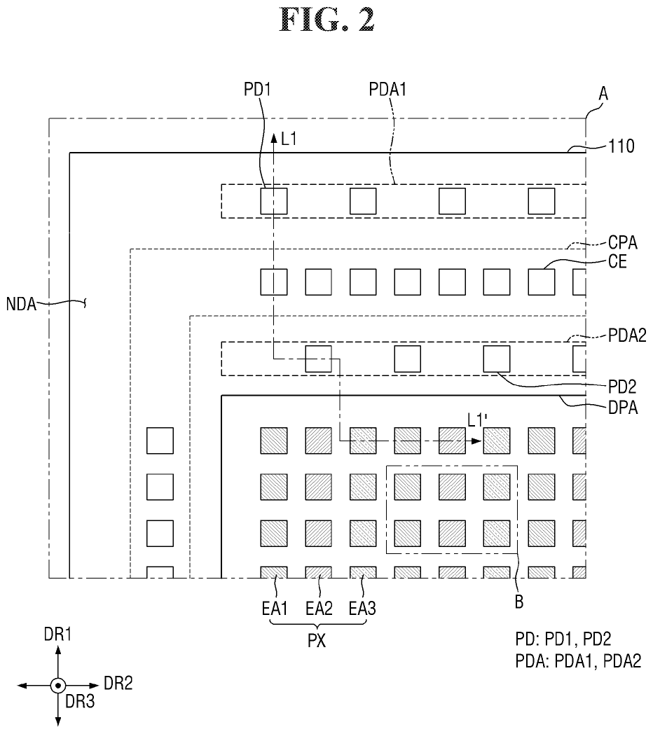

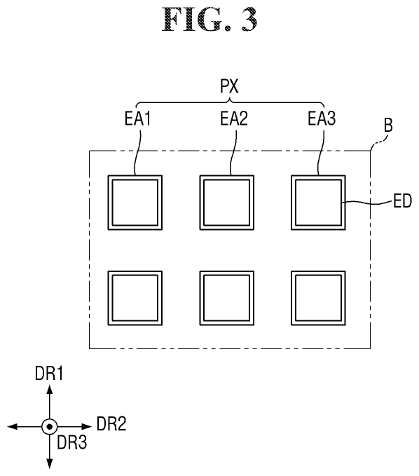

For example, the non-display area NDA may include a plurality of pad areas PDA (PDA1 and PDA2) and a common electrode connection part CPA. The common electrode connection part CPA may surround the display area DPA. The pad areas PDA may be located on a side of, or respective sides of, the common electrode connection part CPA to extend in a direction (e.g., in the second direction DR2). A plurality of pads PD (see FIG. 2) that are electrically connected to an external device are located in the pad areas PDA, and common electrodes CE (see FIG. 2) that are electrically connected to a plurality of light emitting elements ED (see FIG. 3), which are located in the display area DPA, are located in the common electrode connection part CPA.

The pad areas PDA may include a first pad area PDA1, which is an outer pad area located outside the common electrode connection part CPA, and a second pad area PDA2, which is an inner pad area located inside the common electrode connection part CPA. The common electrode connection part CPA may be spaced apart from the display area DPA, and may surround the display area DPA. The first pad area PDA1 may be located outside the common electrode connection part CPA in the non-display area NDA, and the second pad area PDA2 may be located inside the common electrode connection part CPA, and between the display area DPA and the common electrode connection part CPA.

In some embodiments, the first pad area PDA1 and the second pad area PDA2 may each be included in plural numbers in the display device 10, and may be located in the non-display area NDA on both sides of the display area DPA with respect to a first direction DR1. A plurality of first pad areas PDA1 may be located above and below the display area DPA in the first direction DR1, respectively, and may be located outside the common electrode connection part CPA. A plurality of second pad areas PDA2 may be located above and below the display area DPA, respectively, and may be located inside the common electrode connection part CPA.

FIG. 2 is a plan view of a part A of FIG. 1. FIG. 3 is a plan view of a part B of FIG. 2. FIG. 2 is a partial enlarged view of the display area DPA, the pad areas PDA (PDA1 and PDA2), and the common electrode connection part CPA of the display device 10, and FIG. 3 illustrates the planar arrangement of some pixels PX in the display area DPA.

Referring to FIGS. 2 and 3, the display area DPA of the display device 10 may include a plurality of pixels PX. The pixels PX may be arranged in a matrix direction. Each of the pixels PX may be rectangular or square in a plan view. However, the disclosure is not limited thereto, and each of the pixels PX may also have a rhombus shape having each side inclined with respect to a direction. The pixels PX may be arranged in a stripe type or an island type. In addition, each of the pixels PX may display a corresponding color by including one or more light emitting elements that emit light of a corresponding wavelength band.

Each of the pixels PX may include a plurality of emission areas EA1, EA2, and EA3, and in the display device 10, one pixel PX composed of a plurality of emission areas EA1, EA2, and EA3 may have a minimum emission unit.

For example, one pixel PX may include a first emission area EA1, a second emission area EA2, and a third emission area EA3. The first emission area EA1 may emit light of a first color, the second emission area EA2 may emit light of a second color, and the third emission area EA3 may emit light of a third color. For example, the first color may be red, the second color may be green, and the third color may be blue. However, the disclosure is not limited thereto, and the emission areas EA1, EA2, and EA3 may also emit light of the same color. In some embodiments, one pixel PX may include three emission areas EA1, EA2, and EA3, but the disclosure is not limited thereto. For example, one pixel PX may also include four or more emission areas in other embodiments.

Each of the emission areas EA1, EA2, and EA3 may include a light emitting element ED for emitting light of a corresponding color. Although a case where the light emitting element ED has a quadrangular planar shape is described as an example, embodiments of the disclosure are not limited thereto. For example, the light emitting element ED may also have a polygonal, circular, oval, or irregular shape other than the quadrangular shape.

The emission areas EA1, EA2, and EA3 may be arranged in the first direction DR1 and the second direction DR2, and the first emission area EA1, the second emission area EA2, and the third emission area EA3 may be alternately arranged in the first direction DR1. As a plurality of pixels PX are arranged in the first direction DR1 and the second direction DR2, the first emission area EA1, the second emission area EA2, and the third emission area EA3 may be sequentially arranged in the first direction DR1, and this arrangement may be repeated. In addition, each of the first emission area EA1, the second emission area EA2, and the third emission area EA3 may be repeatedly arranged in the second direction DR2.

The display device 10 may include a bank layer BNL surrounding the emission areas EA1, EA2, and EA3, and the bank layer BNL may separate different emission areas EA1, EA2, and EA3 from each other. The bank layer BNL may be spaced apart from the light emitting elements ED and may surround the light emitting elements ED in a plan view. The bank layer BNL may include parts extending in the first direction DR1 and the second direction DR2 to form a mesh, net, or lattice-shaped pattern in a plan view.

Although each of the emission areas EA1, EA2, and EA3 surrounded by the bank layer BNL has a quadrangular planar shape in FIGS. 2 and 3, the disclosure is not limited thereto. The planar shape of each of the emission areas EA1, EA2, and EA3 may be changed variously according to the planar arrangement of the bank layer BNL.

A plurality of common electrodes CE may be located in the common electrode connection part CPA of the non-display area NDA. The common electrodes CE may be spaced apart from each other, and may surround the display area DPA. The common electrodes CE may be electrically connected to the light emitting elements ED located in the display area DPA. In addition, the common electrodes CE may be electrically connected to a semiconductor circuit board.

In the drawings, the common electrode connection part CPA surrounds both sides of the display area DPA in the first direction DR1 and the second direction DR2. However, the disclosure is not limited thereto. The planar arrangement of the common electrode connection part CPA may vary according to the arrangement of the common electrodes CE. For example, when the common electrodes CE are arranged in a direction on a side of the display area DPA, the common electrode connection part CPA may extend in that direction in a plan view.

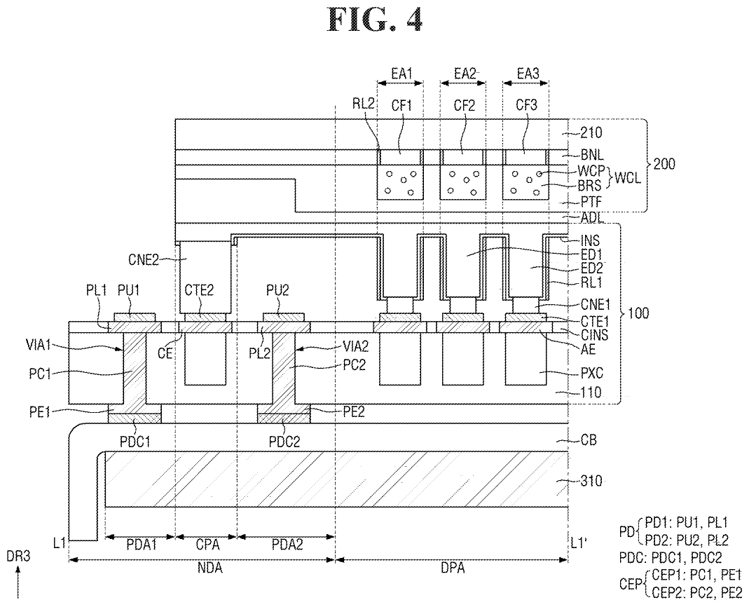

A plurality of pads PD (PD1 and PD2) may be located in each of the pad areas PDA. A plurality of first pads PD1 may be located in the first pad area PDA1, and a plurality of second pads PD2 may be located in the second pad area PDA2. Each of the pads PD1 and PD2 may be electrically connected to a circuit board pad PDC (see FIG. 4) located on an external circuit board CB (see FIG. 4).

The first pads PD1 may be spaced apart from each other in the second direction DR2 in the first pad area PDA1, and the second pads PD2 may be spaced apart from each other in the second direction DR2 in the second pad area PDA2.

The arrangement of the pads PD1 and PD2 may be designed according to the number of light emitting elements ED located in the display area DPA, and according to the arrangement of wirings electrically connected to the light emitting elements ED. In the drawings, the first pads PD1 and the second pads PD2 are not located side by side with each other in the first direction DR1. However, the disclosure is not limited thereto. The first pads PD1 and the second pads PD2 may also be arranged side by side with each other in the first direction DR1, or may be alternately arranged according to the arrangement of the light emitting elements ED and the arrangement of wirings electrically connected to the light emitting elements ED.

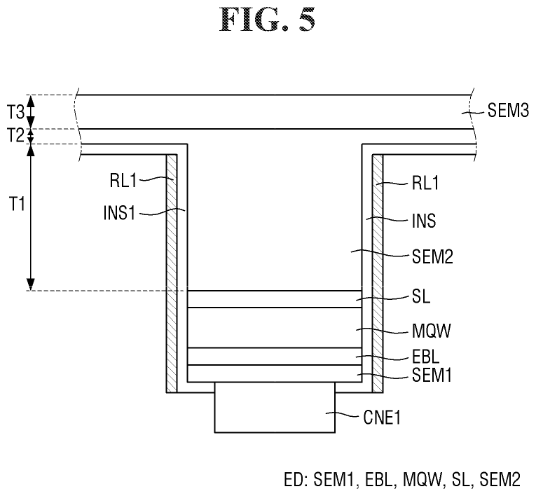

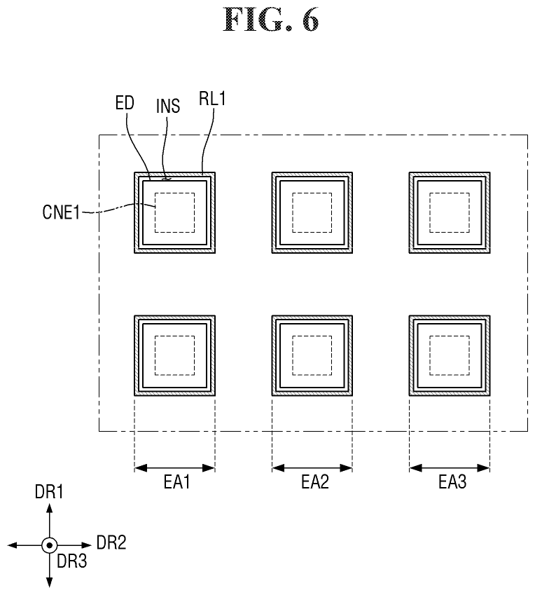

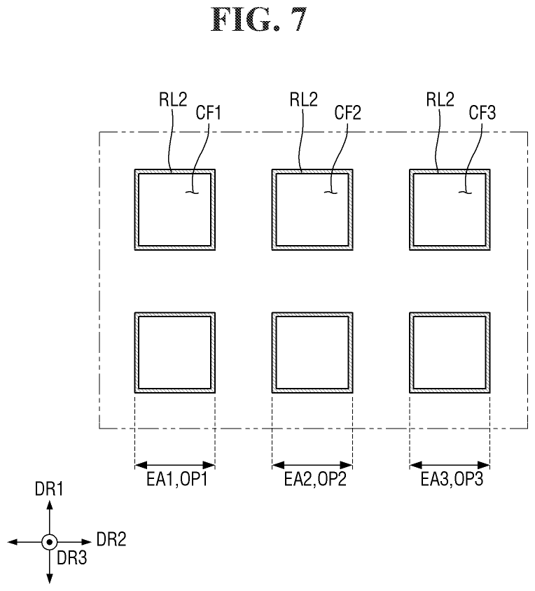

FIG. 4 is a cross-sectional view taken along the line L1-L1′ of FIG. 2. FIG. 5 is a cross-sectional view of a light emitting element ED according to some embodiments. FIG. 6 is a plan view illustrating the arrangement of the light emitting elements ED of the display device 10 according to some embodiments. FIG. 7 is a plan view illustrating the arrangement of color filters CF1, CF2, and CF3 of the display device 10 according to some embodiments. FIG. 4 illustrates a cross section across the pad areas PDA (PDA1 and PDA2), the common electrode connection part CPA, and a pixel PX of the display area DPA.

Referring to FIGS. 4, 5, 6, and 7, in conjunction with FIGS. 1, 2, and 3, the display device 10 according to some embodiments may include a display substrate 100, a color conversion substrate 200, and a circuit board CB. In addition, the display device 10 may further include a heat dissipation substrate 310 located under the display substrate 100.

The display substrate 100 may include a first substrate 110 and a plurality of light emitting elements ED, a plurality of pads PD (PD1 and PD2), and a plurality of electrode connection parts CTE1 and CTE2 located on the first substrate 110. The color conversion substrate 200 may include a second substrate 210, the color filters CF1, CF2, and CF3, and color control structures WCL located on the second substrate 210. The circuit board CB may include circuit board pads PDC located under the first substrate 110, and electrically connected to the pads PD1 and PD2 of the display substrate 100.

The first substrate 110 may be a semiconductor circuit board. The first substrate 110 may be a silicon wafer substrate formed using a semiconductor process, and may include a plurality of pixel circuit units PXC. Each of the pixel circuit units PXC may be formed through a process of forming a semiconductor circuit on a silicon wafer. Each of the pixel circuit units PXC may include at least one transistor and at least one capacitor formed using a semiconductor process. For example, the pixel circuit units PXC may include complementary metal oxide semiconductor (CMOS) circuits.

The pixel circuit units PXC may be located in the display area DPA and the non-display area NDA. Among the pixel circuit units PXC, pixel circuit units PXC located in the display area DPA may be electrically connected to pixel electrodes AE, respectively. The pixel circuit units PXC located in the display area DPA may be located to correspond to the pixel electrodes AE, and may respectively overlap the light emitting elements ED located in the display area DPA in a third direction DR3, which is a thickness direction.

Among the pixel circuit units PXC, pixel circuit units PXC located in the non-display area NDA may be electrically connected to the common electrodes CE, respectively. The pixel circuit units PXC located in the non-display area NDA may be located to correspond to the common electrodes CE, and may respectively overlap the common electrodes CE and second connection electrodes CNE2 located in the non-display area NDA in the third direction DR3.

A circuit insulating layer CINS may be located on the pixel circuit units PXC. The circuit insulating layer CINS may protect the pixel circuit units PXC, and may planarize steps of the pixel circuit units PXC. The circuit insulating layer CINS may expose a part of each of the pixel electrodes AE, so that the pixel electrodes AE may be electrically connected to first connection electrodes CNE1. The circuit insulating layer CINS may include an inorganic insulating material such as silicon oxide (SiOₓ), silicon nitride (SiNₓ), silicon oxynitride (SiOₓN_{y}), aluminum oxide (AlOₓ), or aluminum nitride (AlNₓ).

The pixel electrodes AE may be located in the display area DPA, and may be located on corresponding pixel circuit units PXC, respectively. Each of the pixel electrodes AE may be an exposed electrode that is integrally formed with a pixel circuit unit PXC, and that is exposed from the pixel circuit unit PXC. The common electrodes CE may be located in the common electrode connection part CPA of the non-display area NDA, and may be located on corresponding pixel circuit units PXC, respectively. Each of the common electrodes CE may be an exposed electrode that is integrally formed with a pixel circuit unit PXC and that is exposed from the pixel circuit unit PXC.

The pixel electrodes AE and the common electrodes CE may each include a metal material, such as aluminum (Al).

Each of the electrode connection parts CTE1 and CTE2 may be located on a pixel electrode AE or a common electrode CE. First electrode connection parts CTE1 may be located in the display area DPA, and may be located on the pixel electrodes AE, respectively. The first electrode connection parts CTE1 may correspond to different pixel electrodes AE, respectively. Second electrode connection parts CTE2 may be located in the common electrode connection part CPA of the non-display area NDA to surround the display area DPA, and may be located on the common electrodes CE, respectively.

In an example, each of the electrode connection parts CTE1 and CTE2 may be directly located on a pixel electrode AE or a common electrode CE, respectively, to contact the pixel electrode AE or the common electrode CE. Each of the electrode connection parts CTE1 and CTE2 may be electrically connected to a pixel electrode AE or a common electrode CE and a light emitting element ED. In addition, each of the second electrode connection parts CTE2 may be electrically connected to any one of the pads PD through a pixel circuit unit PXC formed in the non-display area NDA.

Each of the electrode connection parts CTE1 and CTE2 may include a material that may be electrically connected to a pixel electrode AE or a common electrode CE and a light emitting element ED. For example, each of the electrode connection parts CTE1 and CTE2 may include at least any one of gold (Au), copper (Cu), aluminum (Al), and tin (Sn). Alternatively, each of the electrode connection parts CTE1 and CTE2 may include a first layer including any one of gold (Au), copper (Cu), aluminum (Al) ,and tin (Sn), and may include a second layer including another one of gold (Au), copper (Cu), aluminum (Al), and tin (Sn).

The pads PD (PD1 and PD2) are located in the non-display area NDA. The non-display area NDA includes the first pad area PDA1, which is a pad area located outside the common electrode connection part CPA, and the second pad area PDA2, which is a pad area located inside the common electrode connection part CPA. The pads PD (PD1 and PD2) may include the first pads PD1 located in the first pad area PDA1, and the second pads PD2 located in the second pad area PDA2. The first pads PD1 and the second pads PD2 are respectively spaced apart from the common electrodes CE and the second electrode connection parts CTE2. The first pads PD1 may be spaced apart from the common electrodes CE toward the outside of the non-display area NDA (e.g., away from the display area DPA), and the second pads PD2 may be spaced apart from the common electrodes CE toward the inside of the non-display area NDA (e.g., toward the display area DPA) and may be located between the common electrodes CE and the pixel electrodes AE. A distance between light emitting elements ED located at an outermost part of the display area DPA and the first pads PD1 may be greater than a distance between the light emitting elements ED and the second pads PD2. Alternatively, based on the display area DPA, a distance between the display area DPA and the first pad area PDA1 may be greater than a distance between the display area DPA and the second pad area PDA2.

Each of the pads PD may include a pad base layer PL1 or PL2 and a pad upper layer PU1 or PU2. A first pad base layer PL1 of each first pad PD1 may be located on the first substrate 110, and the circuit insulating layer CINS may expose the first pad base layer PL1. A first pad upper layer PU1 of each first pad PD1 may be directly located on the first pad base layer PL1. Similarly, a second pad base layer PL2 of each second pad PD2 may be located on the first substrate 110, and the circuit insulating layer CINS may expose the second pad base layer PL2. A second pad upper layer PU2 of each second pad PD2 may be directly located on the second pad base layer PL2.

The pads PD may be electrically connected to the circuit board pads PDC (PDC1 and PDC2) of the circuit board CB, respectively. The first pads PD1 may be electrically connected to first circuit board pads PDC1 of the circuit board CB, and the second pads PD2 may be electrically connected to second circuit board pads PDC2 of the circuit board CB. Because the first pads PD1 and the second pads PD2 are located in different areas from the common electrode connection part CPA, the first circuit board pads PDC1 and the second circuit board pads PDC2 may be located on the circuit board CB to correspond to the arrangement of the pads PD1 and PD2.

According to some embodiments, in the display device 10, the circuit board CB may be located on a lower surface of the first substrate 110 of the display substrate 100, and the pads PD1 and PD2 may be respectively electrically connected to the circuit board pads PDC through via holes VIA (VIA1 and VIA2) passing through the first substrate 110. The display device 10 may include a plurality of via holes VIA located at positions respectively corresponding to the pads PD1 and PD2 of the pad areas PDA1 and PDA2, and respectively corresponding to pad connection electrodes CEP (CEP1 and CEP2) connecting the pads PD1 and PD2 and the circuit board pads PDC in the via holes VIA.

In the display device 10, the circuit board CB may be located under the display substrate 100, that is, located on a side of the display substrate 100 opposite the other side facing the color conversion substrate 200, and the pads PD may be electrically connected to the circuit board pads PDC of the circuit board CB through the via holes VIA passing through the first substrate 110. The first substrate 110 of the display substrate 100 may include a plurality of wirings that transmit an emission signal for causing the light emitting elements ED of the display area DPA to emit light, and the wirings may be connected to the pads PD located in the pad areas PDA. Each of the pads PD may be electrically connected to a circuit board pad PDC of the circuit board CB to receive the emission signal.

As the number of light emitting elements ED located per unit area in the display area DPA increases, an ultra-high resolution display device can be realized. At the same time, because wirings electrically connected to a relatively large number of light emitting elements ED per unit area are also located with a high degree of integration, it may be suitable to secure a space in which the pads PD electrically connected to the wirings can be located. Because the display device 10 includes the common electrodes CE electrically connected to the light emitting elements ED, it may be suitable to secure a space in which the common electrode connection part CPA and the pad areas PDA are located in the non-display area NDA. To realize an ultra-high resolution display device by placing a large number of light emitting elements ED per unit area, designing the display device 10 to reduce or minimize the non-display area NDA may be considered.

In the display device 10 according to some embodiments, the circuit board CB may be located under the first substrate 110, the pads PD may be electrically connected to the circuit board pads PDC through the via holes VIA passing through the first substrate 110, and some of the pads PD may be located inside the common electrode connection part CPA (e.g., between the common electrode connection part CPA and the display area DPA). The pads PD may be located inside and outside (e.g., located at an interior of and at an exterior of) the common electrode connection part CPA in the non-display area NDA, and the space of the area outside the common electrode connection part CPA may be reduced or minimized. In the display device 10, the area outside the common electrode connection part CPA in the non-display area NDA of the first substrate 110 may be reduced or minimized, and the display area DPA may occupy a relatively large area (e.g., a relatively large portion of the display panel). In the display device 10 according to some embodiments, because the pads PD are electrically connected to the circuit board pads PDC of the circuit board CB through the via holes VIA (VIA and VIA2) passing through the first substrate 110, a sufficient display area DPA can be secured, which may be suitable for realizing an ultra-high resolution display device. The arrangement of the pads PD, the pad connection electrodes CEP, and the via holes VIA will be described in more detail later with reference to other drawings.

The circuit board CB may be a flexible printed circuit board (FPCB), a printed circuit board (PCB), a flexible printed circuit (FPC), or a flexible film such as a chip on film (COF).

The light emitting elements ED may be located in the display area DPA to correspond to the emission areas EA1, EA2, and EA3, respectively. One light emitting element ED may be located in one emission area EA1, EA2, or EA3.

The light emitting elements ED may be respectively located on the first electrode connection parts CTE1 in the display area DPA. Each of the light emitting elements ED may be an inorganic light emitting diode extending in a direction. Each of the light emitting elements ED may have a cylindrical shape, a disk shape, or a rod shape having a width that is greater than a height. However, the disclosure is not limited thereto, and each of the light emitting elements ED may also have various shapes including shapes such as a rod, a wire, or a tube, polygonal prisms such as a cube, a rectangular parallelepiped, or a hexagonal prism, and a shape extending in a direction and having a partially inclined outer surface. In an example, a length of each light emitting element ED in the direction in which the light emitting element ED extends, or a length of each light emitting element ED in the third direction DR3, may be greater than a width in a horizontal direction, and the length of each light emitting element ED in the third direction DR3 may be about 1 μm to about 5 μm.

According to some embodiments, each of the light emitting elements ED may include a first connection electrode CNE1, a first semiconductor layer SEMI, an electron blocking layer EBL, an active layer MQW, a superlattice layer SL, and a second semiconductor layer SEM2. The first connection electrode CNE1, the first semiconductor layer SEMI, the electron blocking layer EBL, the active layer MQW, the superlattice layer SL, and the second semiconductor layer SEM2 may be sequentially stacked in the third direction DR3.

The first connection electrode CNE1 may be located on a first electrode connection part CTE1. The first connection electrode CNE1 may directly contact the first electrode connection part CTE1, and may send an emission signal transmitted to a pixel electrode AE to a light emitting element ED. The first connection electrode CNE1 may be an ohmic connection electrode. However, the disclosure is not limited thereto, and the first connection electrode CNE1 may also be a Schottky connection electrode. Each of the light emitting elements ED may include at least one first connection electrode CNE1.

When each light emitting element ED is electrically connected to an electrode connection part CTE1 or CTE2, the first connection electrode CNE1 may reduce resistance due to contact between the light emitting element ED and the electrode connection part CTE1 or CTE2. The first connection electrode CNE1 may include a conductive metal. For example, the first connection electrode CNE1 may include at least any one of gold (Au), copper (Cu), tin (Sn), titanium (Ti), aluminum (Al), and silver (Ag). For example, the first connection electrode CNE1 may include a 9:1 alloy, an 8:2 alloy, or a 7:3 alloy of gold and tin, or may include an alloy of copper, silver, and tin (e.g., SAC305).

The first semiconductor layer SEMI may be located on the first connection electrode CNE1. The first semiconductor layer SEMI may be a p-type semiconductor, and may include a semiconductor material having a chemical formula of AₓGa_{y}In_{1-x-y}N (0≤x≤1, 0≤y≤1, 0≤x+y≤1). For example, the first semiconductor layer SEM1 may be any one or more of p-type doped AlGaInN, GaN, AlGaN, InGaN, AlN, and InN. The first semiconductor layer SEMI may be doped with a p-type dopant, and the p-type dopant may be Mg, Zn, Ca, Se, Ba, or the like. For example, the first semiconductor layer SEM1 may be p-GaN doped with p-type Mg.

The electron blocking layer EBL may be located on the first semiconductor layer SEM1. The electron blocking layer EBL may reduce or prevent electrons flowing into the active layer MQW from being injected into other layers without recombining with holes in the active layer MQW. For example, the electron blocking layer EBL may be p-AlGaN doped with p-type Mg. A thickness of the electron blocking layer EBL may be in the range of, but is not limited to, about 10 nm to about 50 nm. In some embodiments, the electron blocking layer EBL may be omitted.

The active layer MQW may be located on the electron blocking layer EBL. The active layer MQW may emit light through recombination of electrons and holes according to an emission signal received though the first semiconductor layer SEMI and the second semiconductor layer SEM2. In some embodiments, in each light emitting element ED of the display device 10, the active layer MQW may emit light of the third color, that is, blue light whose central wavelength band is in the range of about 450 nm to about 495 nm.

The active layer MQW may include a material having a single or multiple quantum well structure. When the active layer MQW includes a material having a multiple quantum well structure, it may have a structure in which a plurality of well layers and a plurality of barrier layers are alternately stacked. Here, the well layers may be formed of InGaN, and the barrier layers may be formed of GaN or AIGaN, but the disclosure is not limited thereto.

For example, the active layer MQW may have a structure in which a semiconductor material having a large band gap energy, and a semiconductor material having a small band gap energy, are alternately stacked, or may include different group 3, group 4, or group 5 semiconductor materials depending on the wavelength band of light that it emits. Light emitted from the active layer MQW is not limited to blue light of the third color. In some cases, the active layer MQW may emit red light of the first color or green light of the second color.

The superlattice layer SL is located on the active layer MQW. The superlattice layer SL may relieve stress due to a difference in lattice constant between the second semiconductor layer SEM2 and the active layer MQW. For example, the superlattice layer SL may be formed of InGaN or GaN. A thickness of the superlattice layer SL may be about 50 nm to about 200 nm. However, the superlattice layer SL may also be omitted.

The second semiconductor layer SEM2 may be located on the superlattice layer SL. The second semiconductor layer SEM2 may be an n-type semiconductor. The second semiconductor layer SEM2 may include a semiconductor material having a chemical formula of AlₓGa_{y}In_{1-x-y}N (0≤x≤, 0≤y≤1, 0≤x+y≤1). For example, the second semiconductor layer SEM2 may be any one or more of n-type doped AlGaInN, GaN, AlGaN, InGaN, AlN, and InN. The second semiconductor layer SEM2 may be doped with an n-type dopant, and the n-type dopant may be Si, Ge, Sn, or the like. For example, the second semiconductor layer SEM2 may be n-GaN doped with n-type Si. A thickness of the second semiconductor layer SEM2 may be in the range of, but is not limited to, about 2 μm to 4 μm.

According to some embodiments, the second semiconductor layers SEM2 of the light emitting elements ED of the display device 10 may be connected to each other. The light emitting elements ED may share a part of the second semiconductor layer SEM2 as one common layer, and a plurality of layers located on the second semiconductor layer SEM2 may be spaced apart from each other. The second semiconductor layer SEM2 may include a base layer that extends in the first direction DR1 and in the second direction DR2 to lie in the display area DPA and in a part of the non-display area NDA, and may include a plurality of protruding parts that protrude from the base layer and that are spaced apart from each other. The other layers of each light emitting element ED may be located on (e.g., below) a protruding part of the second semiconductor layer SEM2, and spaced apart from those of another light emitting element ED, and the layers may constitute one light emitting element ED together with the protruding part of the second semiconductor layer SEM2. In the second semiconductor layer SEM2, a thickness T1 of each protruding part that forms a part of a light emitting element ED may be greater than a thickness T2 of the base layer that does not overlap the first semiconductor layer SEMI.

In addition, in the display device 10, the second semiconductor layer SEM2 may transmit an emission signal received through the second connection electrodes CNE2 and the second electrode connection parts CTE2 to the light emitting elements ED. As will be described later, the second connection electrodes CNE2 may be located on (e.g., below) a surface of the base layer of the second semiconductor layer SEM2 located in the non-display area NDA, and the second semiconductor layer SEM2 of the light emitting elements ED may be electrically connected to the common electrodes CE through the second electrode connection parts CTE2.

A third semiconductor layer SEM3 is located on the second semiconductor layer SEM2 of the light emitting elements ED. The third semiconductor layer SEM3 may be located in the display area DPA and in a part of the non-display area NDA, and may be entirely located on the base layer of the second semiconductor layer SEM2. The third semiconductor layer SEM3 may be an undoped semiconductor. The third semiconductor layer SEM3 may include the same material as the second semiconductor layer SEM2, but may be a material not doped with an n-type or p-type dopant. In some embodiments, the third semiconductor layer SEM3 may be, but is not limited to, at least any one of undoped InAlGaN, GaN, AlGaN, InGaN, AlN, and InN.

The third semiconductor layer SEM3 may not have conductivity, unlike the second semiconductor layer SEM2, and an emission signal transmitted to the pixel electrodes AE and the common electrodes CE may flow through the light emitting elements ED and the second semiconductor layer SEM2. In a process of manufacturing the light emitting elements ED, the second semiconductor layer SEM2 and the light emitting elements ED may be formed on the third semiconductor layer SEM3. A thickness T3 of the third semiconductor layer SEM3 may be smaller than the thickness T1 of each protruding part of the second semiconductor layer SEM2, and may be greater than the thickness T2 of the base layer of the second semiconductor layer SEM2.

A plurality of second connection electrodes CNE2 may be located in the common electrode connection part CPA of the non-display area NDA. The second connection electrodes CNE2 may be located on (e.g., below) the surface of the base layer of the second semiconductor layer SEM2. In addition, the second connection electrodes CNE2 may be directly on the second electrode connection parts CTE2, and may transmit an emission signal received from the common electrodes CE to the light emitting elements ED. The second connection electrodes CNE2 may be made of the same material as the first connection electrodes CNE1. A thickness of each second connection electrode CNE2 in the third direction DR3 may be greater than a thickness of each first connection electrode CNE1.

A first insulating layer INS may be located on (e.g., below) the surface of the base layer of the second semiconductor layer SEM2 and on side surfaces of each of the light emitting elements ED. The first insulating layer INS may surround at least the light emitting elements ED. Because parts of the first insulating layer INS that surround the light emitting elements ED are located to correspond to the light emitting elements ED, respectively, they may be spaced apart from each other in the first direction DR1 and in the second direction DR2 in a plan view. The first insulating layer INS may protect each of the light emitting elements ED, and may insulate the second semiconductor layer SEM2 and the light emitting elements ED from other layers. The first insulating layer INS may include an inorganic insulating material such as silicon oxide (SiOₓ), silicon nitride (SiNₓ), silicon oxynitride (SiOₓN_{y}), aluminum oxide (AlO_{y}), or aluminum nitride (AlNₓ).

First reflective layers RL1 may surround the side surfaces of the light emitting elements ED. The first reflective layers RL1 may be located in the display area DPA to correspond to the emission areas EA1, EA2, and EA3, respectively, and may be directly located on the first insulating layer INS located on the side surfaces of the light emitting elements ED. Because the first reflective layers RL1 surround the light emitting elements ED spaced apart from each other, they may be spaced apart from each other in the first direction DR1 and the second direction DR2 in a plan view. The first reflective layers RL1 may reflect light emitted from the active layers MQW of the light emitting elements ED, and the light may travel toward the second substrate 210 instead of toward the first substrate 110.

The first reflective layers RL1 may include a metal material having high reflectivity, such as aluminum (Al). A thickness of each first reflective layer RL1 may be, but is not limited to, about 0.1 μm.

The heat dissipation substrate 310 may be located on a lower side of the display substrate 100, which is opposite an upper side of the display substrate 100 facing the color conversion substrate 200, among both sides of the display substrate 100. The heat dissipation substrate 310 may generally have a shape similar to that of the first substrate 110, and may be located under the circuit board CB. According to some embodiments, at least a part of the heat dissipation substrate 310 may overlap the display area DPA of the display device 10 in the thickness direction, and the other part may overlap the non-display area NDA. The heat dissipation substrate 310 may include a material having relatively high thermal conductivity to effectively dissipate heat generated from the display substrate 100 and the circuit board CB. For example, the heat dissipation substrate 310 may be made of a metal material having high thermal conductivity, such as tungsten (W), aluminum (Al), or copper (Cu).

In some embodiments, the heat dissipation substrate 310 may be located on a lower surface of the circuit board CB to contact the circuit board CB. However, the disclosure is not limited thereto. In some embodiments, the heat dissipation substrate 310 may be structured to efficiently dissipate heat generated in the display device 10, for example, heat generated from the light emitting elements ED. This will be described with reference to other embodiments.

The color conversion substrate 200 is located on the display substrate 100, and includes a protective layer PTF, the color control structures WCL, the color filters CF1, CF2, and CF3, second reflective layers RL2, the bank layer BNL, and the second substrate 210. The above layers of the color conversion substrate 200 may be sequentially located based on the first substrate 110. The layers located on a surface of the second substrate 210 that faces the first substrate 110 will now be sequentially described starting with the second substrate 210.

The second substrate 210 may be located to face the first substrate 110. The second substrate 210 may be a base substrate that supports a plurality of layers included in the color conversion substrate 200. The second substrate 210 may be made of a transparent material. For example, the second substrate 210 may include a transparent substrate, such as a sapphire substrate or glass. However, the disclosure is not limited thereto, and the second substrate 210 may also be made of a conductive substrate such as GaN, SiC, ZnO, Si, GaP, or GaAs.

The bank layer BNL may be located on a surface of the second substrate 210. The bank layer BNL may surround the first emission area EA1, the second emission area EA2, and the third emission area EA3. The bank layer BNL may include parts extending in the first direction DR1 and in the second direction DR2 to form a grid pattern in the entire display area DPA. In addition, the bank layer BNL may also be located in the non-display area NDA, and may completely cover the surface of the second substrate 210 in the non-display area NDA.

The bank layer BNL may include a plurality of openings OP1, OP2, and OP3 exposing the second substrate 210 in the display area DPA. The openings OP1, OP2, and OP3 may include a first opening OP1 overlapping the first emission area EA1, a second opening OP2 overlapping the second emission area EA2, and a third opening OP3 overlapping the third emission area EA3. The openings OP1, OP2, and OP3 may correspond to the emission areas EA1, EA2, and EA3, respectively.

In some embodiments, the bank layer BNL may include silicon (Si). For example, the bank layer BNL may include a silicon monocrystalline layer. The bank layer BNL including silicon may be formed by a reactive ion etching (RIE) process. The bank layer BNL may be formed to have a high aspect ratio by controlling process conditions of the etching process.

The color filters CF1, CF2, and CF3 may be respectively located in the openings OP1, OP2, and OP3 of the bank layer BNL on the surface of the second substrate 210. The different color filters CF1, CF2, and CF3 may be spaced apart from each other with the bank layer BNL interposed between them, but the disclosure is not limited thereto.

The color filters CF1, CF2, and CF3 may include a first color filter CF1, a second color filter CF2, and a third color filter CF3. The first color filter CF1 may be located in the first opening OP1 of the bank layer BNL to overlap the first emission area EA1. The second color filter CF2 may be located in the second opening OP2 of the bank layer BNL to overlap the second emission area EA2, and the third color filter CF3 may be located in the third opening OP3 of the bank layer BNL to overlap the third emission area EA3.

The color filters CF1, CF2, and CF3 may fill the openings OP1, OP2, and OP3, respectively, and a surface of each of the color filters CF1, CF2, and CF3 may be side by side with a surface of the bank layer BNL. That is, a thickness of each of the color filters CF1, CF2, and CF3 may be the same as a thickness of the bank layer BNL. However, the disclosure is not limited thereto, and the surface of each of the color filters CF1, CF2, and CF3 may also protrude from, or may be recessed from, the surface of the bank layer BNL. That is, the thickness of each of the color filters CF1, CF2, and CF3 may also be different from the thickness of the bank layer BNL.

The color filters CF1, CF2, and CF3 located to respectively correspond to the openings OP1, OP2, and OP3 of the bank layer BNL may form island-shaped patterns, but the disclosure is not limited thereto. For example, each of the color filters CF1, CF2, and CF3 may also form a linear pattern extending in a direction in the display area DPA. In this case, the openings OP1, OP2, and OP3 of the bank layer BNL may also extend in the direction. In some embodiments, the first color filter CF1 may be a red color filter, the second color filter CF2 may be a green color filter, and the third color filter CF3 may be a blue color filter. Each of the color filters CF1, CF2, and CF3 may transmit only some of the light of a color that passes through a color control structure WCL after being emitted from a light emitting element ED, and may block transmission of other light of another color.

The second reflective layers RL2 may be located in the openings OP1, OP2, and OP3 of the bank layer BNL. The second reflective layers RL2 may be located on side surfaces of the bank layer BNL, respectively, and may surround side surfaces of the color filters CF1, CF2, and CF3 located in the openings OP1, OP2, and OP3. The second reflective layers RL2 located in different openings OP1, OP2, and OP3 may surround different color filters CF1, CF2, and CF3, respectively, and may be spaced apart from each other in the first direction DR1 and the second direction DR2 in a plan view.

Like the first reflective layers RL1, the second reflective layers RL2 may reflect incident light. Some of the light incident on the color filters CF1, CF2, and CF3 after being emitted from the light emitting elements ED may be reflected by the second reflective layers RL2 toward an upper surface of the second substrate 210. The second reflective layers RL2 may include the same material as the first reflective layers RL1 described above, and may include, for example, a metal material having high reflectivity, such as aluminum (Al). A thickness of each of the second reflective layers RL2 may be, but is not limited to, about 0.1 μm.

The color control structures WCL may be located on the color filters CF1, CF2, and CF3. The color control structures WCL may overlap the first color filter CF1, the second color filter CF2, and the third color filter CF3, respectively, and may be spaced apart from each other. The color control structures WCL may be located to correspond to the openings OP1, OP2, and OP3 located in the bank layer BNL, respectively. In some embodiments, the color control structures WCL may overlap the openings OP1, OP2, and OP3, respectively. The color control structures WCL may be formed as island-shaped patterns spaced apart from each other. However, the disclosure is not limited thereto, and the color control structures WCL may also be formed as linear patterns extending in a direction.

The color control structures WCL may convert or shift a peak wavelength of incident light into light of another corresponding peak wavelength, and may output the light. In some embodiments in which the light emitting elements ED emit blue light of the third color, the color control structures WCL may convert at least a part of the light emitted from the light emitting elements ED into yellow light of a fourth color. A part of the light of third color emitted from the light emitting elements ED may be converted into the yellow light of the fourth color by the color control structures WCL, and a mixture of the light of the third color and the light of the fourth color may be incident on each of the color filters CF1, CF2, and CF3. The first color filter CF1 may transmit red light of the first color among the mixture of the light of the third color and the light of the fourth color, and may block transmission of light of other colors. Similarly, the second color filter CF2 may transmit green light of the second color among the mixture of the light of the third color and the light of the fourth color, and may block transmission of light of other colors. The third color filter CF3 may transmit the blue light of the third color among the mixture of the light of the third color and the light of the fourth color, and may block transmission of other colors.

Each of the color control structures WCL may include a base resin BRS and wavelength conversion particles WCP. The base resin BRS may include a light-transmitting organic material. For example, the base resin BRS may include epoxy resin, acrylic resin, cardo resin, or imide resin. The respective base resins BRS of the color control structures WCL may all be made of the same material, but the disclosure is not limited thereto. The wavelength conversion particles WCP may be materials that convert the blue light of the third color into the yellow light of the fourth color. The wavelength conversion particles WCP may be quantum dots, quantum rods, or phosphors. The quantum dots include group IV nanocrystals, group II-VI compound nanocrystals, group III-V compound nanocrystals, group IV-VI nanocrystals, or a combination of the same.

In addition, each of the color control structures WCL may further include scatterers. The scatterers may be metal oxide particles or organic particles. The metal oxide may be, for example, titanium oxide (TiO₂), zirconium oxide (ZrO₂), aluminum oxide (Al₂O₃), indium oxide (In₂O₃), zinc oxide (ZnO), or tin oxide (SnO₂), and the organic particle material may be, for example, acrylic resin or urethane resin.

As a thickness of the color control structures WCL in the third direction DR3 increases, the content of the wavelength conversion particles WCP included in the color control structures WCP increases, thereby increasing the light conversion efficiency of the color control structures WCL. The thickness of the color control structures WCL may be designed in consideration of the light conversion efficiency of the wavelength conversion particles WCP.

The protective layer PTF may be located on the bank layer BNL and the color control structures WCL and may cover them. The protective layer PTF may be located over the display area DPA and the non-display area NDA. The protective layer PTF may protect the color control structures WCL in the display area DPA, and may planarize steps formed by the color control structures WCL.

The protective layer PTF may be located between the light emitting elements ED and the color control structures WCL, and may prevent the wavelength conversion particles WCP of the color control structures WCL from being damaged by heat generated from the light emitting elements ED. The protective layer PTF may include an organic insulating material such as epoxy resin, acrylic resin, cardo resin, or imide resin.

An adhesive layer ADL may be located between the display substrate 100 and the color conversion substrate 200. The adhesive layer ADL may bond the display substrate 100 and the color conversion substrate 200 to each other, and may be made of a transparent material to transmit light emitted from the light emitting elements ED. For example, the adhesive layer ADL may include an acrylic-based, silicone-based, or urethane-based material, and may include a material that can be UV-cured or heat-cured.

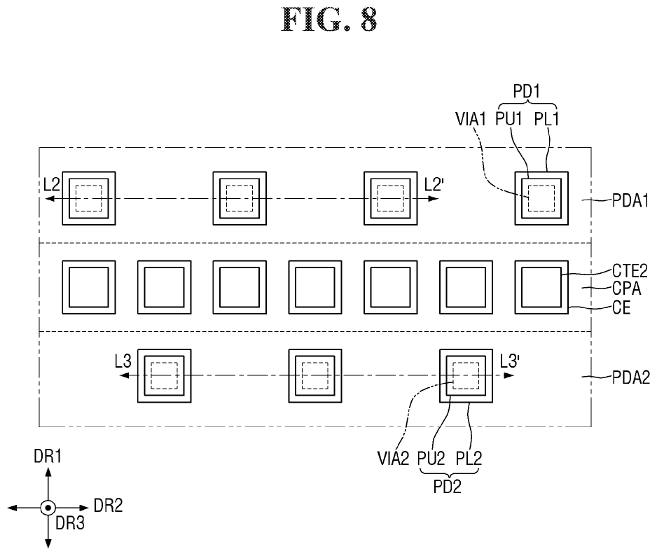

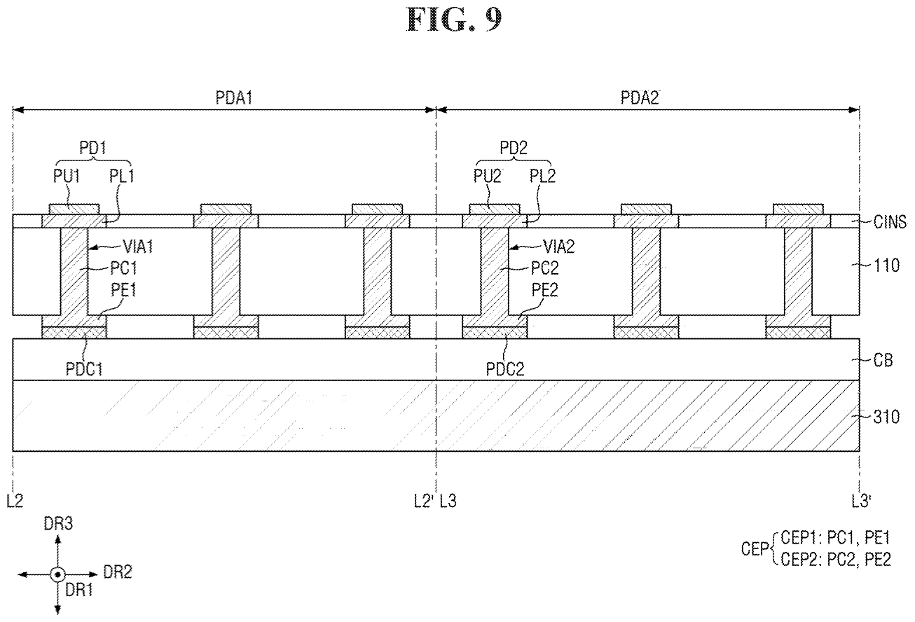

FIG. 8 is a plan view illustrating the arrangement of pad electrodes and the common electrodes CE in the pad areas PDA (PDA1 and PDA2) and the common electrode connection part CPA of the display device 10 according to some embodiments. FIG. 9 is a cross-sectional view taken along the lines L2-L2′ and L3-L3′ of FIG. 8. FIG. 8 illustrates the planar arrangement of the common electrodes CE located in the common electrode connection part CPA of the non-display area NDA and the pads PD located in different pad areas PDA (PDA1 and PDA2). FIG. 9 illustrates a cross section across the first pads PD1 of the first pad area PDA1 and the second pads PD2 of the second pad area PDA2.

Referring to FIGS. 8 and 9 in conjunction with FIG. 4, some of the pads PD (PD1 and PD2) may be located in the first pad area PDA1, and the others may be located in the second pad area PDA2. The first pads PD1 may be spaced apart from each other in the first pad area PDA1, and the second pads PD2 may be spaced apart from each other in the second pad area PDA2. The first pads PD1 and the second pads PD2 may be respectively spaced apart from each other in the second direction DR2. The planar arrangement of the first pads PD1 and the second pads PD2 may vary according to the arrangement design of a plurality of wirings electrically connected to the light emitting elements ED. As illustrated in the drawings, the first pads PD1 and the second pads PD2 may be staggered instead of being located side by side with each other. However, the disclosure is not limited thereto. Depending on the arrangement design of the wirings, the first pads PD1 and the second pads PD2 may also be located side by side with each other in the first direction DR1, or may be arranged without regularity. In some embodiments, the first pads PD1 and the second pads PD2 may be respectively staggered along the second direction DR2 instead of being located side by side with each other.

The common electrodes CE may also be spaced apart from each other in a direction (e.g., the second direction DR2), or may be arranged randomly without regularity in the common electrode connection part CPA. However, because the second electrode connection parts CTE2 are located to correspond to the common electrodes CE, respectively, the planar arrangement of the common electrodes CE and the planar arrangement of the second electrode connection parts CTE2 may be substantially the same.

The pads PD (PD1 and PD2) may be respectively electrically connected to the circuit board pads PDC (PDC1 and PDC2) of the circuit board CB through the via holes VIA (VIA1 and VIA2) and the pad connection electrodes CEP (CEP1 and CEP2) formed in the first substrate 110. The pads PD1 and PD2 may be located on a first surface of the first substrate 110, and the circuit board pads PDC1 and PDC2 may be located on a surface of the circuit board CB. According to some embodiments, the via holes VIA (VIA1 and VIA2) include first via holes VIA1 formed in the first pad area PDA1 of the non-display area NDA, and second via holes VIA2 formed in the second pad area PDA2. The pad connection electrodes CEP may include first pad connection electrodes CEP1 electrically connecting the first pads PD1 and the first circuit board pads PDC1, and second pad connection electrodes CEP2 electrically connecting the second pads PD2 and the second circuit board pads PDC2.

The first via holes VIA1 may be formed to respectively correspond to the first pads PD1 in the first pad area PDA1, and may pass through the first substrate 110. The first via holes VIA1 may pass through the first substrate 110 from the first surface on which the first pads PD1 are located to a second surface. The first via holes VIA1 may overlap the first pads PD1, and the first pad base layers PL1 may be located on the first via holes VIA1. The first pad connection electrodes CEP1 may be partially located in the first via holes VIA1, and may be electrically connected to the first pads PD1 and the first circuit board pads PDC1, respectively. Each of the first pad connection electrodes CEP1 may include a first connection part PC1 located in a first via hole VIA1, and a first electrode part PE1 connected to the first connection part PC1 and located on the lower surface of the first substrate 110. The first connection part PC1 may directly contact the first pad base layer PL1 of a first pad PD1, and the first electrode part PE1 may be located on the second surface of the first substrate 110 to directly contact a first circuit board pad PDC1.

The second via holes VIA2 may be formed to respectively correspond to the second pads PD2 in the second pad area PDA2, and may pass through the first substrate 110. The second via holes VIA2 may pass through the first substrate 110 from the first surface on which the second pads PD2 are located to the second surface. The second via holes VIA2 may overlap the second pads PD2, and the second pad base layers PL2 may be located on the second via holes VIA2. The second pad connection electrodes CEP2 may be partially located in the second via holes VIA2, and may be electrically connected to the second pads PD2 and the second circuit board pads PDC2, respectively. Each of the second pad connection electrodes CEP2 may include a second connection part PC2 located in a second via hole VIA2, and a second electrode part PE2 connected to the second connection part PC2 and located on the lower surface of the first substrate 110. The second connection part PC2 may directly contact the second pad base layer PL2 of a second pad PD2, and the second electrode part PE2 may be located on the second surface of the first substrate 110 to directly contact a second circuit board pad PDC2.

The via holes VIA1 and VIA2 formed in the first substrate 110 may provide paths through which the pads PD1 and PD2 located on the first substrate 110 can be electrically connected to the circuit board pads PDC through the pad connection electrodes CEP, respectively. The first via holes VIA1 may be located in the first pad area PDA1 to correspond to the first pads PD1, and the planar arrangement of the first via holes VIA1 may be substantially the same as the planar arrangement of the first pads PD1. The second via holes VIA2 may be located in the second pad area PDA2 to correspond to the second pads PD2, and the planar arrangement of the second via holes VIA2 may be substantially the same as the planar arrangement of the second pads PD2.

The pad connection electrodes CEP and the circuit board pads PDC may not necessarily completely correspond to the arrangement of the pads PD located on the first substrate 110. In the drawings, the first pad connection electrodes CEP1 and the first circuit board pads PDC1 are located to correspond to the first pads PD1 and the first via holes VIA1, respectively, and the second pad connection electrodes CEP2 and the second circuit board pads PDC2 are located to correspond to the second pads PD2 and the second via holes VIA2, respectively. However, the disclosure is not limited thereto, and the pads PD1 and PD2 may also not correspond to the circuit board pads PDC1 and PDC2, respectively, and the circuit board pads PDC1 and PDC2 may be located to correspond to only some of the pads PD1 and PD2. In the pad connection electrodes CEP1 and CEP2, because the connection parts PC1 and PC2 located in the via holes VIA1 and VIA2 correspond to the via holes VIA1 and VIA2, respectively, they may be located to correspond to the pads PD located on the first substrate 110, respectively. Because the electrode parts PE1 and PE2 contact the circuit board pads PDC1 and PDC2, they may be located to correspond to the circuit board pads PDC1 and PDC2. The pad connection electrodes CEP and the circuit board pads PDC1 and PDC2 may be variously changed according to the design of the pads PD and the structure of the first substrate 110.

In the display device 10, when a relatively large number of light emitting elements ED are located in the display area DPA, and thus the number of wirings electrically connected to the light emitting elements ED is relatively large, a relatively large number of pads PD are, accordingly, suitable. When the pads PD are all located outside the common electrode connection part CPA, an area suitable for the placement of the pads PD may increase, and the pads PD might not be arranged side by side, or may be arranged irregularly. On the other hand, in the display device 10 according to some embodiments, the pad areas PDA1 and PDA2 are located inside and outside the common electrode connection part CPA, respectively. Therefore, the pads PD may be located in a sufficient space. In particular, because only some pads (e.g., the first pads PD1) are located outside the common electrode connection part CPA in the non-display area NDA, the area of an outer part of the non-display area NDA may be reduced or minimized, and the area of the display area DPA per unit area may be relatively increased. Accordingly, a large number of light emitting elements ED per unit area of the first substrate 110 may be located in the display device 10, which is advantageous in realizing an ultra-high resolution display device.

Hereinafter, various embodiments of the display device 10 will be described with further reference to other drawings.

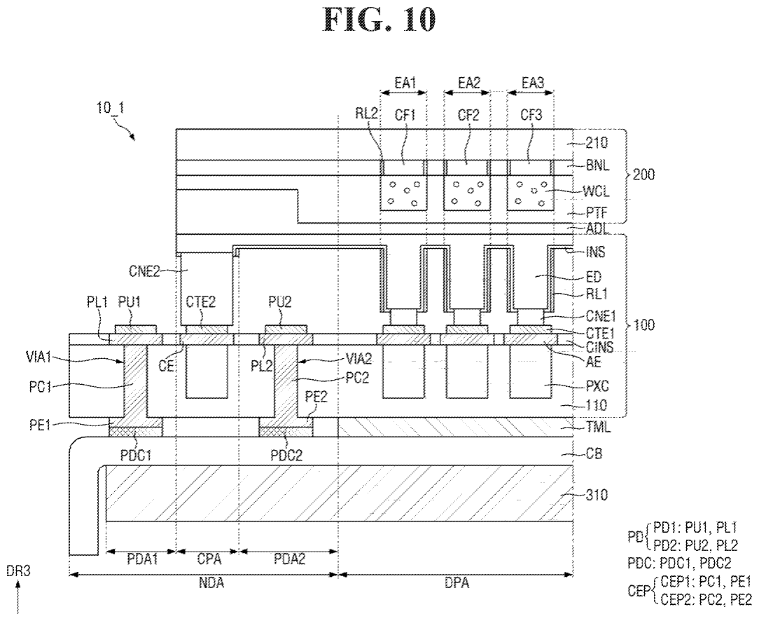

FIG. 10 is a cross-sectional view of a part of a display device 10_1 according to some embodiments.

Referring to FIG. 10, the display device 10_1 according to some embodiments may further include a heat dissipation layer TML located between a first substrate 110 and a heat dissipation substrate 310. To effectively dissipate heat generated in the display device 10_1, the heat dissipation layer TML may include a material having a relatively high thermal conductivity, and may be located under the first substrate 110. The display device 10_1 of some embodiments is different from the embodiments of FIG. 4 in that it further includes the heat dissipation layer TML. Therefore, redundant description will be omitted, and differences will be mainly described below.

The heat dissipation layer TML may include substantially the same material as the heat dissipation substrate 310, and may be located between a circuit board CB and the first substrate 110. In some embodiments, the heat dissipation layer TML may be directly located on a lower surface of the first substrate 110 in an area corresponding to a display area DPA. A surface of the heat dissipation layer TML may directly contact the lower surface of the first substrate 110, and the other surface may directly contact a surface of the circuit board CB. In some embodiments, the heat dissipation layer TML may have a shape that is similar to that of the first substrate 110 in a plan view, and may have an area that is large enough to cover at least the display area DPA.

Unlike in the embodiments of FIG. 4, a space between the first substrate 110 and the circuit board CB may be filled with the heat dissipation layer TML, and heat conduction through the heat dissipation layer TML may be further improved. Because the heat dissipation layer TML directly contacts the first substrate 110, heat generated from light emitting elements ED and pixel circuit units PXC located in the display area DPA may be effectively dissipated. The heat dissipation layer TML may be a path through which heat generated from the light emitting elements ED and the pixel circuit units PXC located in the display area DPA is transferred to the heat dissipation substrate 310. The heat generated from the light emitting elements ED and the pixel circuit units PXC may be transferred to the heat dissipation layer TML, and the heat dissipation layer TML may emit the heat through the circuit board CB and the heat dissipation substrate 310. In some embodiments, because the display device 10_1 includes the heat dissipation layer TML, heat generated from a display substrate 100 can be effectively dissipated, damage to the light emitting elements ED and the pixel circuit units PXC due to heat can be reduced or prevented, and driving efficiency can be improved.

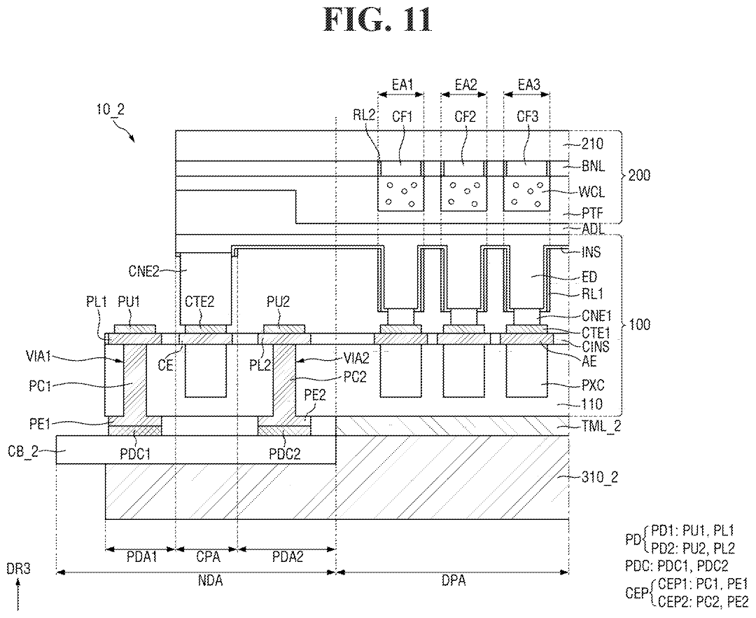

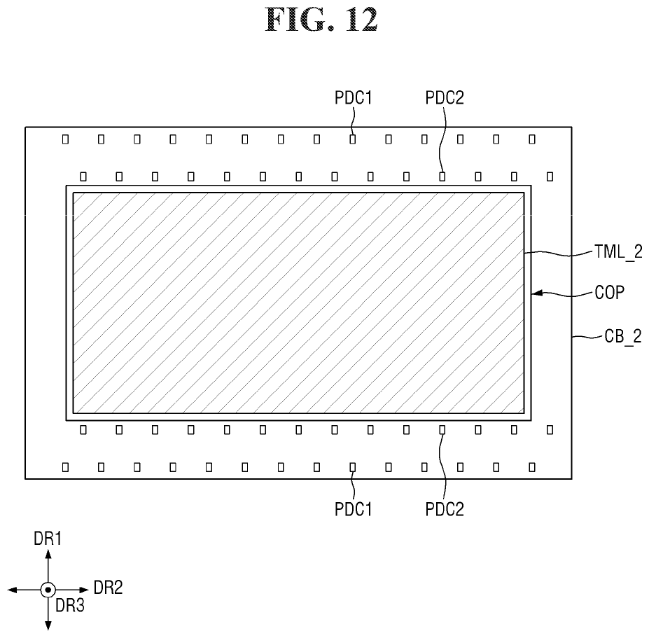

FIG. 11 is a cross-sectional view of a part of a display device 10_2 according to some embodiments. FIG. 12 is a plan view illustrating the relative arrangement of a circuit board CB_2 and a display panel of the display device 10_2 of FIG. 11.

Referring to FIGS. 11 and 12, in the display device 10_2 according to some embodiments, the circuit board CB_2 may include an open hole COP (e.g., a space), and a heat dissipation substrate 310_2 may directly contact a heat dissipation layer TML_2 through the open hole COP. The current embodiments are different from the embodiments of FIG. 10 in that the heat dissipation layer TML_2 directly contacts the heat dissipation substrate 310_2.

The circuit board CB_2 may be made of a material having, relatively, not high thermal conductivity, unlike the heat dissipation layer TML_2 and the heat dissipation substrate 310_2. When a surface of the circuit board CB_2 contacts the heat dissipation layer TML_2, and the other surface of the circuit board CB_2 contacts the heat dissipation substrate 310_2, the temperature of the circuit board CB_2 may rise, thereby damaging other members located on the circuit board CB_2. In addition, when the heat dissipation layer TML_2 directly contacts the heat dissipation substrate 310_2, heat can be dissipated more effectively than when the circuit board CB_2 is interposed between the heat dissipation layer TML_2 and the heat dissipation substrate 310_2. In the display device 10_2 according to some embodiments, the circuit board CB_2 located on a lower surface of a first substrate 110 may include the open hole COP, and the heat dissipation layer TML_2 may be located in the open hole COP. A part of the heat dissipation substrate 310_2 may contact the other surface of the circuit board CB_2, and the other part may directly contact the heat dissipation layer TML_2 in the open hole COP.

The open hole COP of the circuit board CB_2 may be formed to correspond to a display area DPA of the display device 10_2. Because a plurality of circuit board pads PDC are located on the circuit board CB_2 in an area corresponding to a non-display area NDA, the open hole COP may be formed in the other area. Similar to the arrangement relationship between the display area DPA and pad areas PDA1 and PDA2, the circuit board pads PDC may be located on both sides of the open hole COP with respect to the first direction DR1.

The heat dissipation layer TML_2 may be located in the open hole COP of the circuit board CB_2 to directly contact the lower surface of the first substrate 110 in the display area DPA. A size of the heat dissipation layer TML_2 may be the same as, or smaller than, a size of the open hole COP of the circuit board CB_2, and the heat dissipation layer TML_2 may not directly contact the circuit board CB_2.

The heat dissipation substrate 310_2 may be located on a lower surface of the circuit board CB_2, and a part of the heat dissipation substrate 310_2 may be located in the open hole COP of the circuit board CB_2. Because the heat dissipation substrate 310_2 has a different thickness according to position, a part of the heat dissipation substrate 310_2 may be located on the lower surface of the circuit board CB_2, and the other part may be located on a lower surface of the heat dissipation layer TML_2 in the open hole COP of the circuit board CB_2. The heat dissipation substrate 310_2 may directly contact each of the lower surfaces of the circuit board CB_2 and the heat dissipation layer TML_2. Because the heat dissipation substrate 310_2 directly contacts the heat dissipation layer TML_2, heat generated from light emitting elements ED and pixel circuit units PXC can be dissipated more effectively.

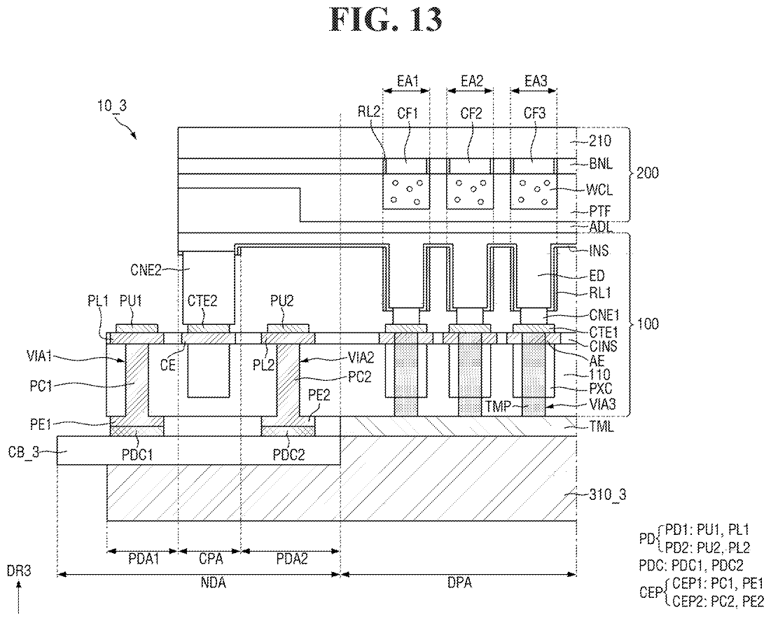

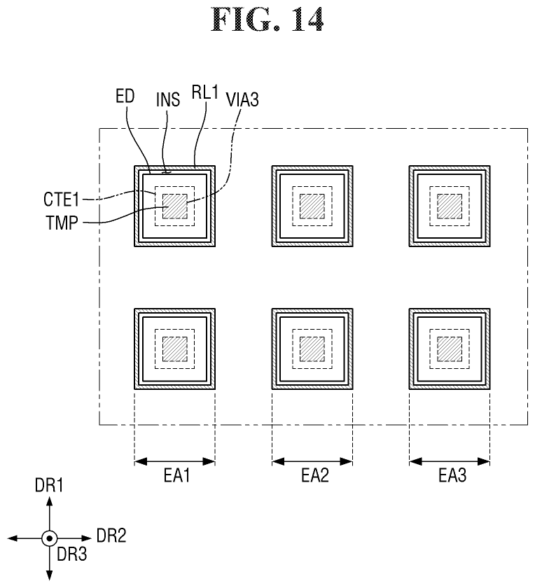

FIG. 13 is a cross-sectional view of a part of a display device 10_3 according to some embodiments. FIG. 14 is a plan view illustrating the arrangement of third via holes VIA3 formed in emission areas of the display device 10_3 of FIG. 13.

Referring to FIGS. 13 and 14, the display device 10_3 according to some embodiments may include a plurality of third via holes VIA3 formed in a display area DPA of a first substrate 110 and overlapping light emitting elements ED, and heat dissipation patterns TMP may be located in the third via holes VIA3, respectively. The light emitting elements ED may be inorganic light emitting diodes, and may generate a relatively large amount of heat when emitting light. To more effectively dissipate the heat, the display device 10_3 according to some embodiments may form dissipation paths of light generated from the light emitting elements ED by including the heat dissipation patterns TMP formed to correspond to at least some of the light emitting elements ED. The display device 10_3 of some embodiments is different from the embodiments of FIG. 12 in that it further includes the third via holes VIA3 and the heat dissipation patterns TMP formed in the display area DPA.

The third via holes VIA3 may be formed in the display area DPA to correspond to at least some of the light emitting elements ED. For example, the third via holes VIA3 may be formed to correspond to the light emitting elements ED, respectively, and may be spaced apart from each other in the first direction DR1 and in the second direction DR2 in a plan view. The third via holes VIA3 may be smaller in size than the light emitting elements ED and first electrode connection parts CTE1, and may be formed to correspond to the light emitting elements ED. The third via holes VIA3 may be formed to pass through pixel electrodes AE and the first substrate 110. The third via holes VIA3 may be formed to overlap the light emitting elements ED, first connection electrodes CNE1, and the first electrode connection parts CTE1, respectively, and the first electrode connection parts CTE1 may be located on the third via holes VIA3. The pixel electrodes AE may be penetrated by the third via holes VIA3, respectively, but may be smoothly electrically connected to the first electrode connection parts CTE1 because the area of each pixel electrode AE is larger than the diameter of each third via hole VIA3.

In the drawings, the third via holes VIA3 are formed to pass through pixel circuit units PXC. However, this is merely an example used for ease of description, and the third via holes VIA3 may not necessarily pass through the pixel circuit units PXC. The third via holes VIA3 may be substantially formed in an area not passing through a plurality of transistors and capacitors of the pixel circuit units PXC.

The heat dissipation patterns TMP may be located in the third via holes VIA3, respectively, to directly contact the first electrode connection parts CTE1 and a heat dissipation layer TML. The heat dissipation patterns TMP may be formed to fill the third via holes VIA3, and upper and lower sides of the heat dissipation patterns TMP may respectively contact the first electrode connection parts CTE1 and the heat dissipation layer TML to form heat dissipation paths. Heat generated from the light emitting elements ED may be transferred to the heat dissipation patterns TMP through the first connection electrodes CNE1 and the first electrode connection parts CTE1. The heat transferred to the heat dissipation patterns TMP may be dissipated through the heat dissipation layer TML and a heat dissipation substrate 310_3, thereby further improving the heat dissipation efficiency of the display device 10_3.

Similar to the heat dissipation substrate 310_3 and the heat dissipation layer TML, the heat dissipation patterns TMP may include a material having a relatively high thermal conductivity. Pad connection electrodes CEP or the heat dissipation patterns TMP may be located in via holes VIA1, VIA2, and VIA3 formed in the first substrate 110, and may include different materials according to their role. For example, the pad connection electrodes CEP may include a material having high electrical conductivity because they electrically connect pads PD1 and PD2 to circuit board pads PDC. On the other hand, the heat dissipation patterns TMP may include a material having high thermal conductivity because they form heat dissipation paths. However, in some embodiments, the pad connection electrodes CEP and the heat dissipation patterns TMP may each include a material having a relatively high electrical conductivity and relatively high thermal conductivity and may include the same material. For example, because a metal material generally has high thermal conductivity and electrical conductivity, the pad connection electrodes CEP and the heat dissipation patterns TMP may include the same material.

In the embodiments of FIGS. 13 and 14, because the third via holes VIA3 are formed to correspond to the light emitting elements ED, respectively, the planar arrangement of the third via holes VIA3 may be substantially the same as the planar arrangement of the light emitting elements ED. However, when the display device 10_3 is an ultra-high resolution display device including a large number of light emitting elements ED, it may not be easy to form the third via holes VIA3 corresponding to the light emitting elements ED, respectively. In the display device 10_3 according to some embodiments, the third via holes VIA3 may not necessarily be formed to completely correspond to the light emitting elements ED, but may be formed to correspond to only some of the light emitting elements ED.

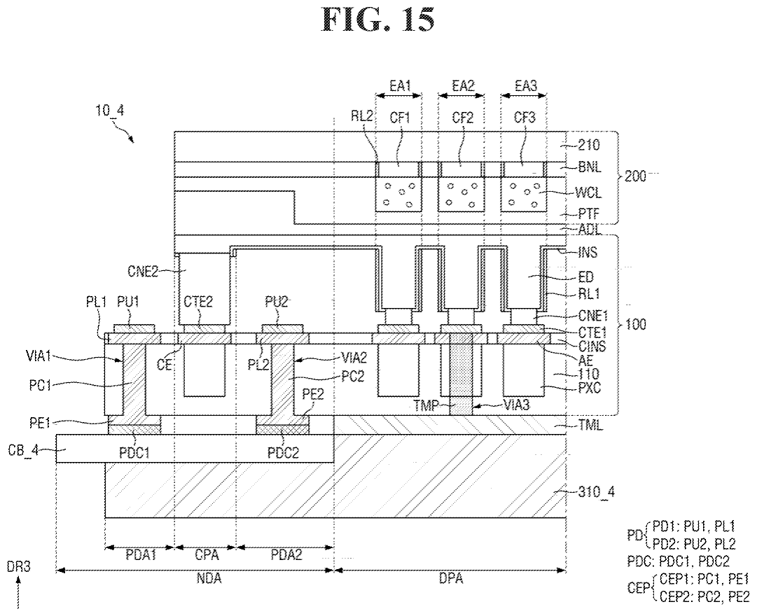

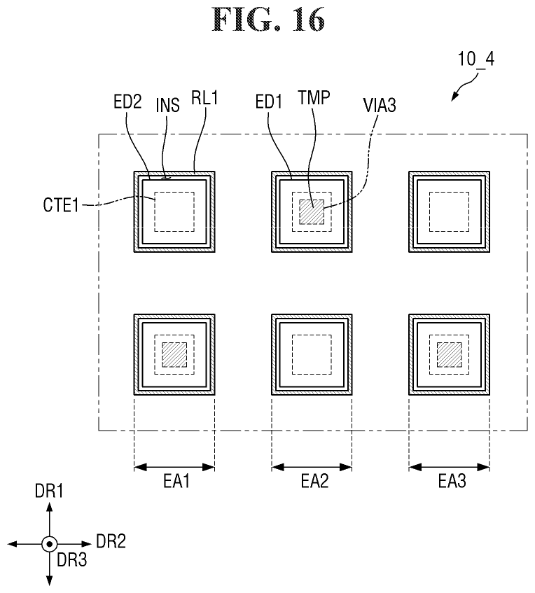

FIG. 15 is a cross-sectional view of a part of a display device 10_4 according to some embodiments. FIG. 16 is a plan view illustrating the arrangement of third via holes VIA3 formed in emission areas of the display device 10_4 of FIG. 15.

Referring to FIGS. 15 and 16, the display device 10_4 according to some embodiments may include a plurality of third via holes VIA3 formed in a display area DPA of a first substrate 110, and formed to correspond to some of light emitting elements ED, and heat dissipation patterns TMP may be located in the third via holes VIA3, respectively. Some embodiments are different from the embodiments of FIGS. 13 and 14 in that the third via holes VIA3 are not necessarily formed to correspond to the light emitting elements ED.

Because the third via holes VIA3 are formed to correspond to some of the light emitting elements ED, the number of light emitting elements ED located in the display area DPA may be different from the number of third via holes VIA3 and the number of heat dissipation patterns TMP. In some embodiments in which the third via holes VIA3 are formed to correspond to some of the light emitting elements ED, the number of third via holes VIA3 and the number of heat dissipation patterns TMP may be less than the number of light emitting elements ED in the display device 10_4, and the light emitting elements ED may be divided into first light emitting elements ED1 overlapping the third via holes VIA3 and second light emitting elements ED2 not overlapping the third via holes VIA3.

First electrode connection parts CTE1 corresponding to the first light emitting elements ED1 may directly contact the heat dissipation patterns TMP through the third via holes VIA3, whereas first electrode connection parts CTE1 corresponding to the second light emitting elements ED2 do not directly contact the heat dissipation patterns TMP. Heat generated from the first light emitting elements ED1 may be emitted to the heat dissipation patterns TMP through first connection electrodes CNE1 and the first electrode connection parts CTE1, and heat generated from the second light emitting elements ED2 may be emitted to the first electrode connection parts CTE1 of adjacent first light emitting elements ED1 through first connection electrodes CNE1 and the first electrode connection parts CTE1. The first light emitting elements ED1 and the second light emitting elements ED2 may have different heat dissipation paths, and thus may be different in the amount of heat generated and the amount of light emitted. The display device 10_4 according to some embodiments may have a process advantage because the third via holes VIA3 are formed to correspond to some of the light emitting elements ED, and may reduce a difference in light emission of the light emitting elements ED1 and ED2, which are divided according to whether they overlap the third via holes VIA3, through an emission signal for compensating for the difference.

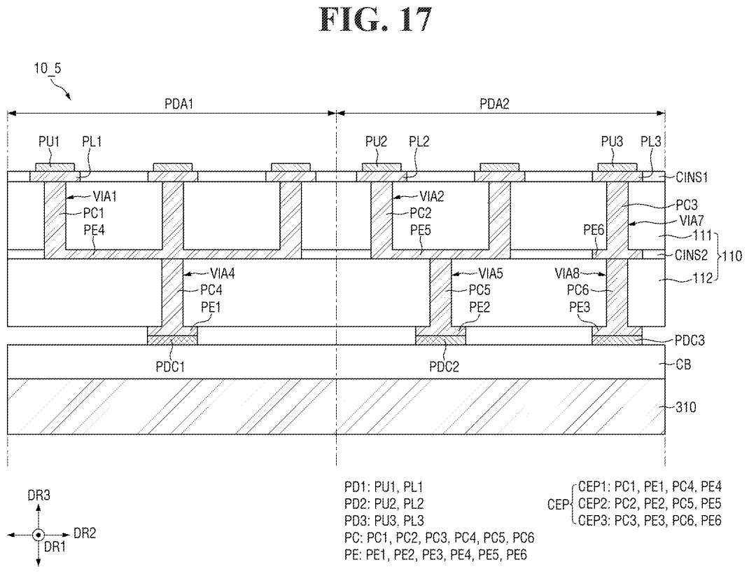

FIG. 17 is a cross-sectional view of pad electrodes located in pad areas PDA1 and PDA2 of a display device 10_5 according to some embodiments.

Referring to FIG. 17, in the display device 10_5 according to some embodiments, a first substrate 110 (111 and 112) may be composed of a plurality of layers, and each of pad connection electrodes CEP (CEP1, CEP2, and CEP3) may include a larger number of connection parts PC and electrode parts PE. Some of a plurality of pads PD (PD1, PD2, and PD3) located in a display substrate 100 may receive the same electrical signal from a circuit board CB, but may be physically separated from each other. Some of a plurality of wirings located in the display substrate 100 may receive the same signal, but may be different from each other, and different pads PD may be located at distal ends of these wirings. If a structure, in which pads PD to which the same electrical signal is transmitted are connected to one circuit board pad PDC, is implemented, then the number of circuit board pads PDC located on the circuit board CB can be reduced, and an unnecessary space of the circuit board CB can be reduced or minimized.

In the display device 10_5 according to some embodiments, the first substrate 110 of the display substrate 100 may include a first substrate layer 111 that includes pixel circuit units PXC, and on which the pads PD are located, and may include a second substrate layer 112 that does not include the pixel circuit units PXC. The pads PD located on the first substrate layer 111 may be connected to the circuit board pads PDC through the pad connection electrodes CEP located in via holes VIA1, VIA2, and VIA7 of the first substrate layer 111, and located in via holes VIA4, VIA5, and VIA8 of the second substrate layer 112. In each of the pad connection electrodes CEP, an electrode part PE (PE4 or PE5) located between the first substrate layer 111 and the second substrate layer 112 is concurrently or substantially simultaneously connected to a plurality of connection parts PC (PC1 or PC2). Therefore, the number of connection parts PC4 or PC5 and the number of via holes VIA4 or VIA5 located in the second substrate layer 112 can be reduced.

For example, the first substrate layer 111 may include a plurality of via holes VIA1, VIA2, and VIA7 formed to correspond, respectively, to pads PD1, PD2, and PD3 located on the first substrate layer 111. First via holes VIA1 may be located in a first pad area PDA1 to correspond to first pads PD1 to which the same electrical signal is transmitted. For example, n first pads PD1 may be located in the first pad area PDA1, and n first via holes VIA1 may be formed in the first pad area PDA1 of the first substrate layer 111. Similarly, second via holes VIA2 may be located in a second pad area PDA2 to correspond to second pads PD2 to which the same electrical signal is transmitted, and a seventh via hole VIA7 may be located in the second pad area PDA2 to correspond to a third pad PD3 to which another electrical signal is transmitted.

In the drawing, three first via holes VIA1 are formed to correspond to three first pads PD1, two second via holes VIA2 are formed to correspond to two second pads PD2, and one seventh via hole VIA7 is formed to correspond to one third pad PD3. Here, the via holes VIA1, VIA2, and VIA7 are distinguished from each other to distinguish the pads PD1, PD2, and PD3 connected to each other by the pad connection electrodes CEP, which will be described later, and the second via holes VIA2 and the seventh via hole VIA7 may be substantially the same. The first via holes VIA1 may be located in the first pad area PDA1, and thus may be distinguished from other via holes VIA2 and VIA7. On the other hand, the second via holes VIA2 and the seventh via hole VIA7 may all be located in the second pad area PDA2, and thus may not be distinguished from each other. They may be distinguished from each other according to electrical signals transmitted to the second pads PD2 and the third pad PD3 located thereon. For example, the same signal may be transmitted to the second pads PD2 located on the second via holes VIA2, and a signal different from the signal transmitted to the second pads PD2 may be transmitted to the third pad PD3 located on the seventh via hole VIA7.

The second substrate layer 112 may include a plurality of via holes VIA4, VIA5, and VIA8 formed to correspond to the circuit board pads PDC. A fourth via hole VIA4 may be formed to correspond to a first circuit board pad PDC1 located on an area of the circuit board CB that is located in the first pad area PDA1. A fifth via hole VIA5 and an eighth via hole VIA8 may be formed to correspond, respectively, to a second circuit board pad PDC2 and a third circuit board pad PDC3 located on an area of the circuit board CB that is located in the second pad area PDA2.

The number of pads PD may correspond to the number of wirings located in the display substrate 100, whereas the number of circuit board pads PDC corresponds to the type of signal transmitted to the wirings. The number of pads PD may be determined according to the arrangement of light emitting elements ED and wirings located in a display area DPA, and the number of circuit board pads PDC may be determined according to the type and number of signals transmitted for light emission of the light emitting elements ED. When signals transmitted to the wirings are different from each other, the number of pads PD and the number of circuit board pads PDC may be equal to each other. However, when some of the signals transmitted to the wirings are the same, the number of pads PD and the number of circuit board pads PDC may be different from each other. When the same signal is transmitted to some wirings, the number of circuit board pads PDC may be less than the number of pads PD, and the number of via holes VIA4, VIA5, and VIA8 formed in the second substrate layer 112 may be fewer than the number of via holes VIA1, VIA2, and VIA7 formed in the first substrate layer 111.

For example, when the same signal is transmitted to the first pads PD1, the first pads PD1 may be connected to one first circuit board pad PDC1. A plurality of, for example, three first via holes VIA1 may be formed to correspond to the number of first pads PD1, and one fourth via hole VIA4 may be formed to correspond to the first circuit board pad PDC1. Similarly, when the same signal is transmitted to the second pads PD2, the second pads PD2 may be connected to one second circuit board pad PDC2. A plurality of, for example, two second via holes VIA2 may be formed to correspond to the number of second pads PD2 to which the same signal is transmitted, and one fifth via hole VIA5 may be formed to correspond to the second circuit board pad PDC2. The third pad PD3 to which a signal that is different from the signal transmitted to the second pads PD2 is transmitted may be connected to one third circuit board pad PDC3. One seventh via hole VIA7 and one eighth via hole VIA8 may be formed to correspond to the third pad PD3 and the third circuit board pad PDC3.

The pad connection electrodes CEP (CEP1, CEP2, and CEP3) may be located in the via holes VIA1, VIA2, VIA4, VIA5, VIA7, and VIA8 of the first substrate layer 111 and the second substrate layer 112, and may connect the pads PD to corresponding circuit board pads PDC, respectively.

A first pad connection electrode CEP1 may include a plurality of first connection parts PC1 located in the first via holes VIA1, a fourth connection part PC4 located in the fourth via hole VIA4, a first electrode part PE1 located on the first circuit board pad PDC1, and a fourth electrode part PE4 connecting the first connection parts PC1 and the fourth connection part PC4. The number of first connection parts PC1 and the number of fourth connection parts PC4 may correspond to the number of first via holes VIA1 and the number of fourth via holes VIA4, respectively. In some embodiments in which three first via holes VIA1 are formed, three first connection parts PC1 and one fourth connection part PC4 may be formed. Because the first electrode part PE1 is formed to correspond to the circuit board pad PDC, the first pad connection electrode CEP1 may include one first electrode part PE1.

The fourth electrode part PE4 may also be formed in a number corresponding to the number of circuit board pads PDC or the number of first electrode parts PE1, but may be connected to a plurality of first connection parts PC1. The fourth electrode part PE4 may be formed to have a greater width than the first electrode part PE1, and may be concurrently or substantially simultaneously connected to the first connection parts PC1. The first pads PD1 to which the same signal is transmitted may be electrically connected to each other through the fourth electrode part PE4 of the first pad connection electrode CEP1, and may be electrically connected to one first circuit board pad PDC1 through the fourth connection part PC4 and the first electrode part PE1.

A second pad connection electrode CEP2 may include a plurality of second connection parts PC2 located in the second via holes VIA2, a fifth connection part PC5 located in the fifth via hole VIA5, a second electrode part PE2 located on the second circuit board pad PDC2, and a fifth electrode part PE5 connecting the second connection parts PC2 and the fifth connection part PC5. The number of second connection parts PC2 and the number of fifth connection parts PC5 may correspond to the number of second via holes VIA2 and the number of fifth via holes VIA5, respectively. Therefore, the second pad connection electrode CEP2 may include two second connection parts PC2 and one fifth connection part PC5. Because the second electrode part PE2 is formed to correspond to the second circuit board pad PDC2, the second pad connection electrode CEP2 may include one second electrode part PE2.

The fifth electrode part PE5 may also be formed in a number corresponding to the number of circuit board pads PDC or the number of second electrode parts PE2, but may be connected to a plurality of second connection parts PC2. The fifth electrode part PE5 may be formed to have a greater width than the second electrode part PE2, and may be concurrently or substantially simultaneously connected to the second connection parts PC2. The second pads PD2 to which the same signal is transmitted may be electrically connected to each other through the fifth electrode part PE5 of the second pad connection electrode CEP2, and may be electrically connected to one second circuit board pad PDC2 through the fifth connection part PC5 and the second electrode part PE2.

A third pad connection electrode CEP3 may also be formed in the same manner as described above. However, in some embodiments in which one third pad PD3 is connected to one third circuit board pad PDC3, the third pad connection electrode CEP3 may include a third connection part PC3, a sixth connection part PC6, a third electrode part PE3, and a sixth electrode part PE6, and the third electrode part PE3 and the sixth electrode part PE6 may have substantially the same width.

The pads PD1, PD2, or PD3 to which the same signal is transmitted among the pads PD, may be electrically connected to the same circuit board pad PDC. Accordingly, in the display device 10_5, the number of circuit board pads PDC can be reduced, and an unnecessary space of the circuit board CB can be reduced or minimized.

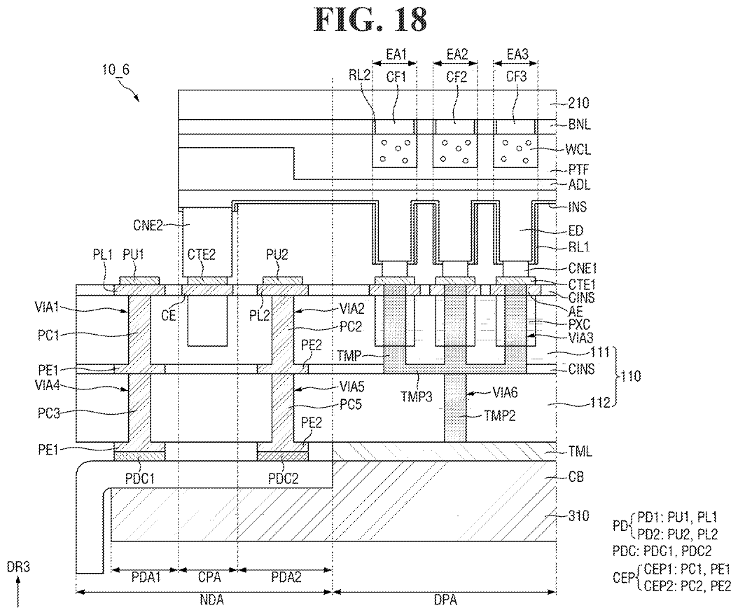

FIG. 18 is a cross-sectional view of a part of the display device 10_5 of FIG. 17.

Referring to FIG. 18, in the display device 10_5 according to some embodiments, the first substrate 110 may include the first substrate layer 111 and the second substrate layer 112, and heat dissipation patterns TMP (TMP1, TMP2, and TMP3) may be connected to each other, like the pad connection electrodes CEP.

The first substrate layer 111 may include a plurality of third via holes VIA3 formed to correspond to the light emitting elements ED in the display area DPA, and the second substrate layer 112 may include a sixth via hole VIA6 formed to correspond to some of the third via holes VIA3 in the display area DPA. The heat dissipation patterns TMP may include a plurality of first heat dissipation patterns TMP1 located in the third via holes VIA3, a second heat dissipation pattern TMP2 located in the sixth via hole VIA6, and a third heat dissipation pattern TMP3 connecting the first heat dissipation patterns TMP1 and the second heat dissipation pattern TMP2.

Heat generated from the light emitting elements ED may be dissipated through the first heat dissipation patterns TMP1. The first heat dissipation patterns TMP1 may be connected to the second heat dissipation pattern TMP2 through the third heat dissipation pattern TMP3, and the heat may be transferred to a heat dissipation layer TMP through the first heat dissipation patterns TMP1, the third heat dissipation pattern TMP3, and the second heat dissipation pattern TMP2. In some embodiments, the heat dissipation patterns TMP1, TMP2, and TMP3 located on different layers because the first substrate 110 includes different substrate layers 111 and 112 are connected to form a dissipation path of the heat generated from the light emitting elements ED.

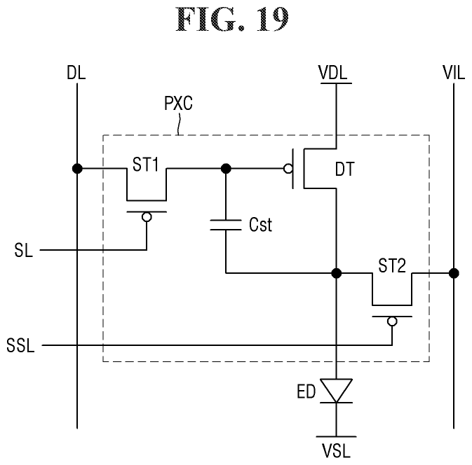

FIG. 19 is a circuit diagram of a pixel circuit unit PXC and a light emitting element ED according to some embodiments. FIG. 19 illustrates an example of a pixel circuit unit PXC and a light emitting element ED of FIG. 4.

Referring to FIG. 19, the light emitting element ED emits light according to a driving current. The amount of light emitted from the light emitting element ED may be proportional to the driving current. The light emitting element ED may be an inorganic light emitting element including an anode, a cathode, and an inorganic semiconductor located between the anode and the cathode.

The anode of the light emitting element ED may be connected to a source electrode of a driving transistor DT, and the cathode may be connected to a second power line VSL to which a low-potential voltage, which is lower than a high-potential voltage, is supplied.

The driving transistor DT adjusts a current flowing from a first power line VDL, to which a first power supply voltage is supplied, to the light emitting element ED according to a voltage difference between a gate electrode and the source electrode. The driving transistor DT may have the gate electrode connected to a first electrode of a first transistor ST1, the source electrode connected to the anode of the light emitting element ED, and a drain electrode connected to the first power line VDL to which a high-potential voltage is applied.

The first transistor ST1 is turned on by a scan signal of a scan line SL to connect a data line DL to the gate electrode of the driving transistor DT. The first transistor ST1 may have a gate electrode connected to the scan line SL, the first electrode connected to the gate electrode of the driving transistor DT, and a second electrode connected to the data line DL.

A second transistor ST2 is turned on by a sensing signal of a sensing signal line SSL to connect an initialization voltage line VIL to the source electrode of the driving transistor DT. The second transistor ST2 may have a gate electrode connected to the sensing signal line SSL, a first electrode connected to the initialization voltage line VIL, and a second electrode connected to the source electrode of the driving transistor DT.

The first electrode of each of the first and second transistors ST1 and ST2 may be a source electrode, and the second electrode may be a drain electrode. However, the disclosure is not limited thereto. That is, the first electrode of each of the first and second transistors ST1 and ST2 may also be a drain electrode, and the second electrode may be a source electrode.

A capacitor Cst is formed between the gate electrode and the source electrode of the driving transistor DT. The capacitor Cst stores a difference voltage between a gate voltage and a source voltage of the driving transistor DT.

Although a case where the driving transistor DT and the first and second transistors ST1 and ST2 are formed as N-type metal oxide semiconductor field effect transistors (MOSFETs) has been mainly described in FIG. 19, it should be noted that the disclosure is not limited thereto. The driving transistor DT and/or the first and/or second transistors ST1 and ST2 may also be formed as P-type MOSFETs.

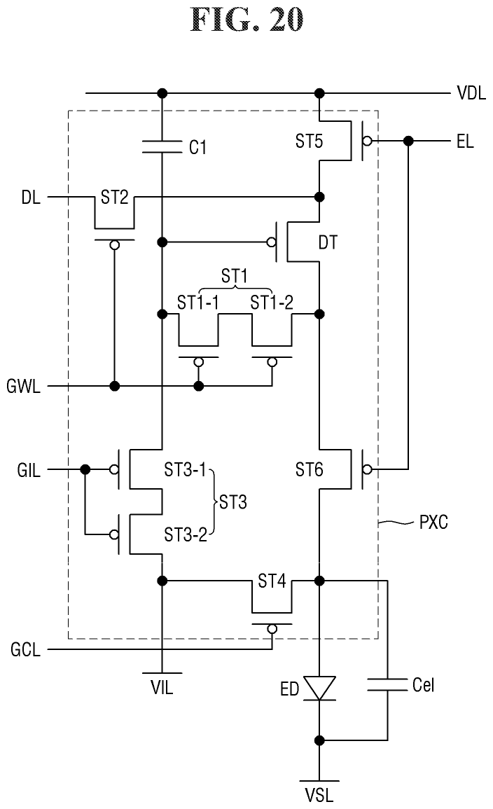

FIG. 20 is a circuit diagram of a pixel circuit unit PXC and a light emitting element ED according to some embodiments. FIG. 20 illustrates an example of a pixel circuit unit PXC and a light emitting element ED of FIG. 4.

Referring to FIG. 20, the light emitting element ED emits light according to a driving current. The amount of light emitted from the light emitting element ED may be proportional to the driving current. The light emitting element ED may be an inorganic light emitting element including an anode, a cathode, and an inorganic semiconductor located between the anode and the cathode.

The anode of the light emitting element ED may be connected to a first electrode of a fourth transistor ST4 and to a second electrode of a sixth transistor ST6, and the cathode may be connected to a second power line VSL. A parasitic capacitance Cel may be formed between the anode and the cathode of the light emitting element ED.

The pixel circuit unit PXC includes a driving transistor DT, switch elements, and a capacitor C1. The switch elements include first through sixth transistors ST1, ST2, ST3, ST4, ST5, and ST6.

The driving transistor DT includes a gate electrode, a first electrode, and a second electrode. The driving transistor DT controls the driving current, which is a drain-source current flowing between the first electrode and the second electrode of the driving transistor DT, according to a data voltage applied to the gate electrode.

The capacitor Cl is formed between the second electrode of the driving transistor DT and a first power line VDL. An electrode of the capacitor Cl may be connected to the second electrode of the driving transistor DT, and the other electrode may be connected to the first power line VDL.

When a first electrode of each of the first through sixth transistors ST1, ST2, ST3, ST4, ST5, and ST6 and the driving transistor DT is a source electrode, a second electrode may be a drain electrode. Alternatively, when the first electrode of each of the first through sixth transistors ST1, ST2, ST3, ST4, ST5, and ST6 and the driving transistor DT is a drain electrode, the second electrode may be a source electrode,

An active layer of each of the first through sixth transistors ST1, ST2, ST3, ST4, ST5, and ST6 and the driving transistor DT may be made of any one of polysilicon, amorphous silicon, and an oxide semiconductor. When a semiconductor layer of each of the first through sixth transistors ST1, ST2, ST3, ST4, ST5, and ST6 and the driving transistor DT is made of polysilicon, a process for forming the semiconductor layer may be a low-temperature polysilicon (LTPS) process.

In addition, although a case where the first through sixth transistors ST1, ST2, ST3, ST4, ST5, and ST6 and the driving transistor DT are formed as P-type MOSFETs has been mainly described in FIG. 20, the disclosure is not limited thereto. The first through sixth transistors ST1, ST2, ST3, ST4, ST5, and ST6 and the driving transistor DT may also be formed as N-type MOSFETs.

Further, a first power supply voltage of the second power line VSL, a second power supply voltage of the first power line VDL, and a third power supply voltage of a third power line VIL may be set in consideration of characteristics of the driving transistor DT, characteristics of the light emitting element ED, and the like.

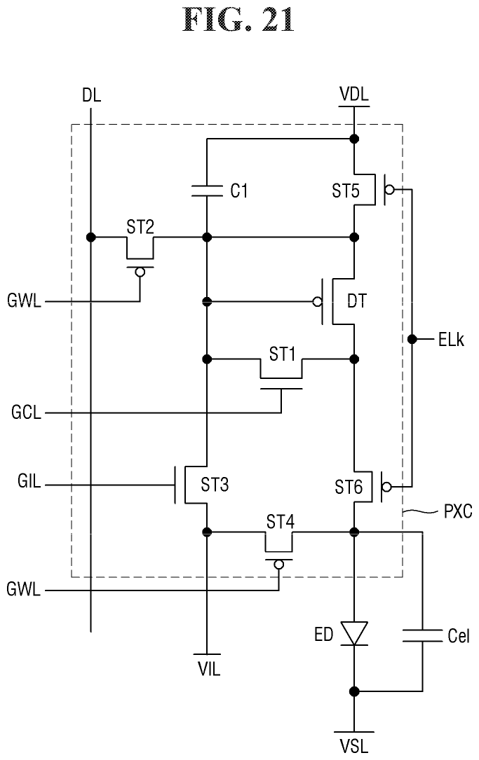

FIG. 21 is a circuit diagram of a pixel circuit unit PXC and a light emitting element ED according to some embodiments. FIG. 21 illustrates an example of a pixel circuit unit PXC and a light emitting element ED of FIG. 4.

The embodiments of FIG. 21 is different from the embodiments of FIG. 20 in that a driving transistor DT, a second transistor ST2, a fourth transistor ST4, a fifth transistor STS, and a sixth transistor ST6 are formed as P-type MOSFETs, and a first transistor ST1 and a third transistor ST3 are formed as N-type MOSFETs.

Referring to FIG. 21, an active layer of each of the driving transistor DT, the second transistor ST2, the fourth transistor ST4, the fifth transistor ST5, and the sixth transistor ST6 formed as P-type MOSFETs may be made of polysilicon, and an active layer of each of the first transistor ST1 and the third transistor ST3 formed as N-type MOSFETs may be made of an oxide semiconductor.

The embodiments of FIG. 21 are different from the embodiments of FIG. 20 in that a gate electrode of the second transistor ST2 and a gate electrode of the fourth transistor ST4 are connected to write scan lines GWL, and a gate electrode of the first transistor ST1 is connected to a control scan line GCL. In addition, because the first transistor ST1 and the third transistor ST3 are formed as N-type MOSFETs in FIG. 21, a scan signal of a gate-high voltage may be transmitted to the control scan line GCL and to an initialization scan line GIL. In contrast, because the second transistor ST2, the fourth transistor ST4, the fifth transistor ST5, and the sixth transistor ST6 are formed as P-type MOSFETs, a scan signal of a gate-low voltage may be transmitted to the write scan lines GWL and an emission line EL.

The pixel circuit unit PXC according to some embodiments is not limited to those illustrated in FIGS. 19, 20, and 21. The pixel circuit unit PXC may also be formed in a circuit structure other than the embodiments illustrated in FIGS. 19, 20, and 21. Meanwhile, a display device for displaying an image according to some embodiments may be applied to various devices and apparatuses.

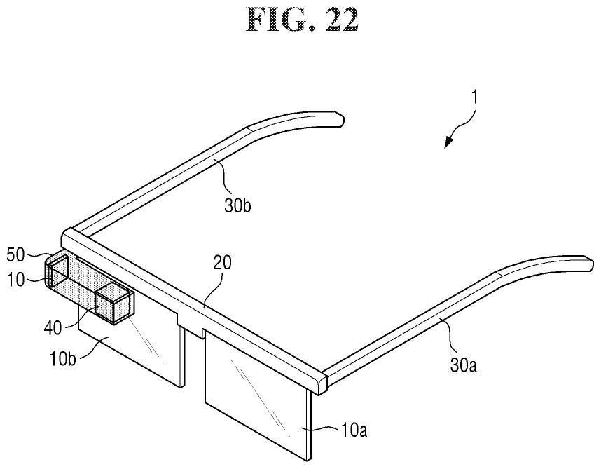

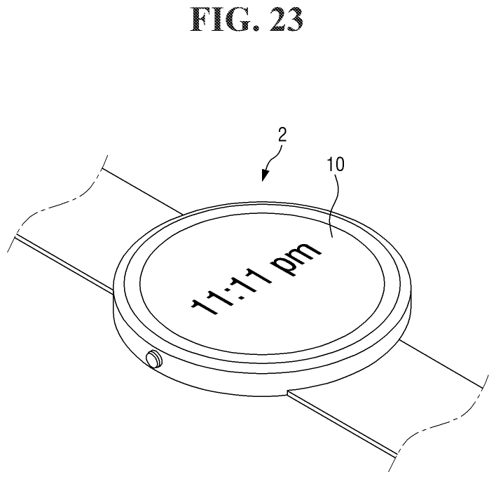

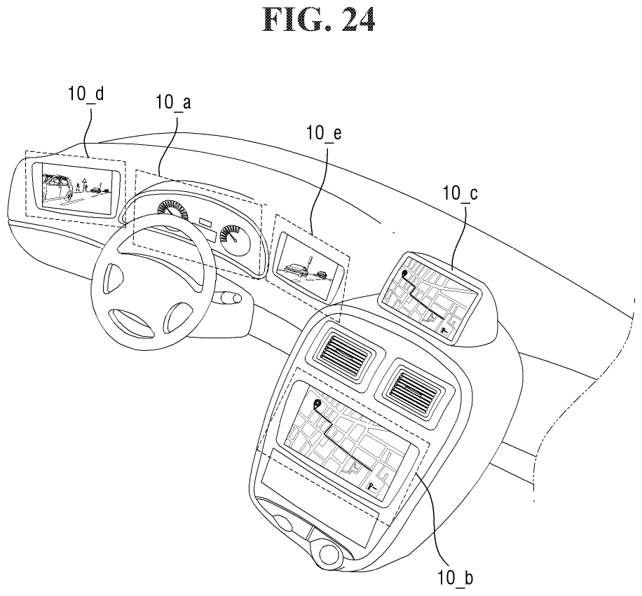

FIGS. 22, 23, and 24 are schematic views of devices including a display device according to some embodiments. FIG. 22 illustrates a virtual reality (VR) device 1 to which a display device 10 according to some embodiments is applied, and FIG. 23 illustrates a smart watch 2 to which a display device 10 according to some embodiments is applied. FIG. 24 illustrates display units of a vehicle to which display devices 10_a, 10_b, 10_c, 10_d, and 10_e according to some embodiments are applied.

Referring to FIG. 22, a VR device 1 according to some embodiments may be a device in the form of glasses. The VR device 1 according to some embodiments may include a display device 10, a left lens 10a, a right lens 10b, a support frame 20, eyeglass frame legs 30a and 30b, a reflective member 40, and a display device accommodating unit 50.

In FIG. 22, the VR device 1 including the eyeglass frame legs 30a and 30b is illustrated as an example. However, the VR device 1 according to some embodiments may also be applied to a head-mounted display including a head-mounted band, which can be mounted on the head, instead of the eyeglass frame legs 30a and 30b. The VR device 1 according to some embodiments is not limited to the structure illustrated in the drawing and can be applied in various forms in various other electronic devices.

The display device accommodating unit 50 may include the display device 10 and the reflective member 40. An image displayed on the display device 10 may be reflected by the reflective member 40 and provided to a user's right eye through the right lens 10b. Accordingly, the user may view a VR image displayed on the display device 10 through the right eye.

The display device accommodating unit 50 may be located at a right end of the support frame 20, but the disclosure is not limited thereto. For example, the display device accommodating unit 50 may also be located at a left end of the support frame 20, and an image displayed on the display device 10 may be reflected by the reflective member 40 and provided to the user's left eye through the left lens 10a. Accordingly, the user may view a VR image displayed on the display device 10 through the left eye. Alternatively, the display device accommodating unit 50 may be located at both the right end and the left end of the support frame 20. In this case, the user may view a VR image displayed on the display device 10 through both the left eye and the right eye.

Referring to FIG. 23, a display device 10 according to some embodiments may be applied to a smart watch 2 which is one of smart devices.

Referring to FIG. 24, display devices 10_a, 10_b, and 10_c according to some embodiments may be applied to a dashboard of a vehicle, a center fascia of the vehicle, or a center information display (CID) located on the dashboard of the vehicle. In addition, display devices 10_d and 10_e according to some embodiments may be applied to room mirror displays that replace side mirrors of the vehicle.

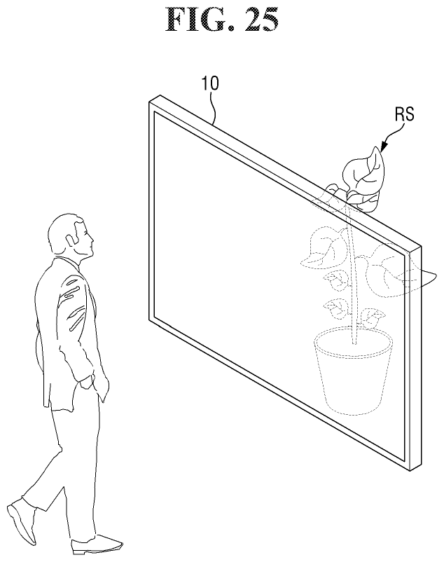

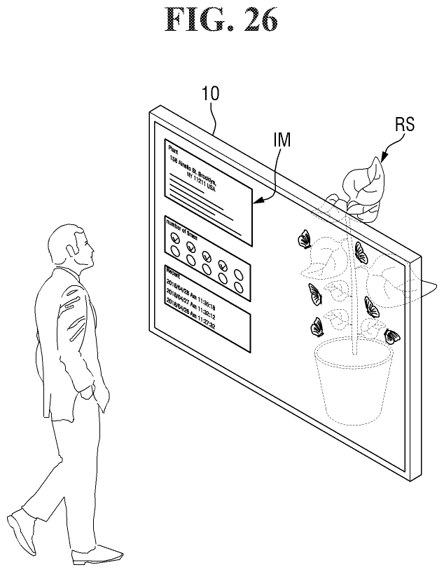

FIGS. 25 and 26 illustrate a transparent display device including a display device 10 according to some embodiments.

Referring to FIGS. 25 and 26, the display device 10 according to some embodiments may be applied to the transparent display device. The transparent display device may transmit light while displaying an image IM. A user located in front of the transparent display device may not only view the image IM displayed on the display device 10 but also view an object RS or the background located behind the transparent display device. When the display device 10 is applied to the transparent display device, a first substrate 110, a heat dissipation substrate 310, and a circuit board CB of the display device 10 of the previously described embodiments may each include a light transmitting part that can transmit light or may be made of a material that can transmit light.

In a display device according to some embodiments, pads of a circuit board and pads of a display substrate may be connected to each other through a substrate on which light emitting elements are located. Accordingly, the display device can secure a sufficient area in which the light emitting elements are located per unit area, which is advantageous in realizing an ultra-high resolution display device.

In addition, the display device may further include a heat dissipation structure located under the substrate on which the light emitting elements are located to effectively dissipate heat generated from the light emitting elements.

In concluding the detailed description, those skilled in the art will appreciate that many variations and modifications can be made to the disclosed embodiments without substantially departing from the present disclosure. Therefore, the disclosed embodiments of the present disclosure are used in a generic and descriptive sense only and not for purposes of limitation. The above and other aspects of the present disclosure will become more apparent to one of daily skill in the art to which the present disclosure pertains by referencing the claims, with functional equivalents thereof to be included therein.

What is claimed is:

1. A display device comprising:
a first substrate comprising a display area, and a non-display area on at least one side of the display area;
light emitting elements on a first surface of the first substrate in the display area;
a connection electrode on the first surface of the first substrate in the non-display area, and electrically connected to the light emitting elements;
first pads in the non-display area and spaced from the connection electrode in a direction;
second pads spaced from the connection electrode in another direction;
a circuit board on a second surface of the first substrate, and comprising a first circuit board pad and a second circuit board pad on a first surface of the circuit board;
a first pad connection electrode connected to the first pads and the first circuit board pad, and comprising a first connection part in a first via hole corresponding to the first pads and passing through the first substrate, and a first electrode part on the second surface of the first substrate; and
a second pad connection electrode connected to the second pads and the second circuit board pad, and comprising a second connection part in a second via hole corresponding to the second pads and passing through the first substrate, and a second electrode part on the second surface of the first substrate.

2. The display device of claim 1, wherein a distance between a light emitting element in an outermost part of the display area among the light emitting elements and the first pads is greater than a distance between the light emitting element in the outermost part of the display area and the second pads.

3. The display device of claim 1, wherein the first connection part directly contacts the first pads,
wherein the second connection part directly contacts the second pads,
wherein the first electrode part directly contacts the first circuit board pad, and
wherein the second electrode part directly contacts the second circuit board pad.

4. The display device of claim 3, wherein the first electrode part of the first pad connection electrode and the first circuit board pad correspond to the first pads, and
wherein the second electrode part of the second pad connection electrode and the second circuit board pad correspond to the second pads.

5. The display device of claim 3, wherein the first substrate comprises a first substrate layer in which the first via hole and the second via hole are formed, and a second substrate layer on a lower surface of the first substrate layer and in which third via holes and fourth via holes are formed,
wherein the first pad connection electrode further comprises a third connection part in the third via holes, and a third electrode part that contacts first connection parts and the third connection part, and
wherein the second pad connection electrode further comprises a fourth connection part in the fourth via holes, and a fourth electrode part that contacts second connection parts and the fourth connection part.

6. The display device of claim 5, wherein a number of first electrode parts of the first pad connection electrode and a number of first circuit board pads are fewer than a number of first pads.

7. The display device of claim 1, further comprising a heat dissipation layer between the first substrate and the circuit board in the display area,
wherein the circuit board is below the second surface of the first substrate to overlap the non-display area and a part of the display area.

8. The display device of claim 7, wherein the heat dissipation layer overlaps the light emitting elements, and directly contacts the second surface of the first substrate and the first surface of the circuit board.

9. The display device of claim 7, further comprising a heat dissipation pattern directly contacting the heat dissipation layer and located in fifth via holes corresponding to at least some of the light emitting elements and passing through the first substrate.

10. The display device of claim 9, wherein the fifth via holes correspond to the light emitting elements in the display area.

11. The display device of claim 9, wherein the first pad connection electrode and the second pad connection electrode comprise a same material as the heat dissipation pattern.

12. The display device of claim 9, wherein the first substrate comprises pixel electrodes that correspond to the light emitting elements in the display area, and a common electrode that corresponds to the connection electrode in the non-display area, and
wherein the fifth via holes pass through at least some of the pixel electrodes.

13. The display device of claim 7, further comprising a heat dissipation substrate on a second surface of the circuit board and located in the display area and the non-display area.

14. The display device of claim 1, wherein the circuit board defines an open hole corresponding to the display area, and wherein the display device further comprises a heat dissipation layer in the open hole of the circuit board to contact the second surface of the first substrate.

15. The display device of claim 14, further comprising a heat dissipation substrate on the second surface of the circuit board and located in the display area and the non-display area,
wherein a part of the heat dissipation substrate in the display area directly contacts the heat dissipation layer.

16. The display device of claim 1, wherein the light emitting elements each comprise a first semiconductor layer, an active layer on the first semiconductor layer, and a second semiconductor layer on the active layer,
wherein the display device further comprises a third semiconductor layer above the first substrate and located on a surface of the second semiconductor layer of the light emitting elements, and
wherein the connection electrode is directly on the first semiconductor layer.

17. The display device of claim 16, wherein the second semiconductor layers of the light emitting elements are connected to each other through a base layer thereof that is located on a surface of the third semiconductor layer in the display area and the non-display area.

18. A display device comprising:
a first substrate comprising a display area in which light emitting elements are located, and a non-display area surrounding the display area;
common electrodes in the non-display area to surround the display area and spaced apart from each other;
first pads outside the common electrodes in the non-display area;
second pads between the common electrodes and the display area;
a circuit board on a second surface of the first substrate, which is opposite to a first surface of the first substrate on which the light emitting elements are located, and comprising first circuit board pads and second circuit board pads;
first pad connection electrodes in first via holes passing through the first substrate and corresponding to the first pads, and respectively contacting the first pads and the first circuit board pads; and
second pad connection electrodes in second via holes passing through the first substrate and corresponding to the second pads, and respectively contacting the second pads and the second circuit board pads.

19. The display device of claim 18, wherein the light emitting elements are arranged in a first direction, and in a second direction intersecting the first direction,
wherein the first pads are spaced apart from at least some of the common electrodes in the first direction, and
wherein the second pads are spaced apart from at least some of the common electrodes in a direction that is opposite to the first direction.

20. The display device of claim 19, wherein at least some of the first pads are not located side by side with the second pads in the first direction.

21. The display device of claim 18, further comprising a heat dissipation layer overlapping the light emitting elements in the display area, and directly contacting the second surface of the first substrate.

22. The display device of claim 21, further comprising heat dissipation patterns directly contacting the heat dissipation layer, and located in third via holes passing through the first substrate and corresponding to at least some of the light emitting elements.
